(19) United States
(12) Patent Application Publication
(10) Pub. No.: US 2022/0320431 A1
(43) Pub. Date: Oct. 6, 2022

(54) VARYING NITROGEN CONTENT IN SWITCHING LAYER OF TWO-TERMINAL RESISTIVE SWITCHING DEVICES

(71) Applicant: CROSSBAR, INC., Santa Clara, CA (US)

(72) Inventors: Sundar Narayanan, Cupertino, CA (US); Yunyu Wang, San Jose, CA (US); Zhen Gu, Cupertino, CA (US); Wee Chen Gan, Cupertino, CA (US); Wei Ti Lee, San Jose, CA (US); Xiesen Yang, San Jose, CA (US)

(21) Appl. No.: 17/218,583

(22) Filed: Mar. 31, 2021

(51) Int. Cl. H01L 45/00; H01L 27/24

(52) U.S. Cl. CPC H01L 45/1625; H01L 45/1253; H01L 45/146; H01L 27/2472; H01L 27/2436

(57) ABSTRACT

Two-terminal resistive switching devices can have a switching layer in which a filament forms and deforms to varying degrees to represent distinct logical states. This switching layer can be formed having a varying ratio, X, of nitrogen to silicon at various strata of the switching layer. Such can result in a two-terminal memory device with improved stability and other characteristics. The switching layer can be formed in a vacuum chamber in which the gas mixture has a ratio, Y, of nitrogen gas to argon gas that is varied during fabrication

### INCORPORATION BY REFERENCE

U.S. Pat. No. 10,608,180 filed Aug. 14, 2017 and titled “RESISTIVE MEMORY CELL WITH INTRINSIC CURRENT CONTROL”, U.S. Pat. No. 9,735,357 filed Feb. 1, 2016 and titled “RESISTIVE MEMORY CELL WITH INTRINSIC CURRENT CONTROL”, U.S. Pat. No. 10,840,442 filed May 19, 2016 and titled “NON-STOICHIOMETRIC RESISTIVE SWITCHING MEMORY DEVICE AND FABRICATION METHODS” and U.S. Provisional application No. 62/165,874, filed May 22, 2016 are each hereby expressly incorporated by reference herein in their respective entireties and for all purposes.

### TECHNICAL FIELD

This disclosure generally relates to two-terminal resistive switching devices with a resistive switching layer having a nitrogen content that is varied.

### BACKGROUND

Resistive-switching memory represents a recent innovation within the field of integrated circuit technology. While much of resistive-switching memory technology is in the development stage, various technological concepts for resistive-switching memory have been demonstrated by the inventor(s) and are in one or more stages of verification to prove or disprove associated theories or techniques. The inventor(s) believe that resistive-switching memory technology shows compelling evidence to hold substantial advantages over competing technologies in the semiconductor electronics industry.

The inventor(s) believe that resistive-switching memory cells can be configured to have multiple states with distinct resistance values. For instance, for a single bit cell, the restive-switching memory cell can be configured to exist in a relatively low resistance state or, alternatively, in a relatively high resistance state. Multi-bit cells might have additional states with respective resistances that are distinct from one another and distinct from the relatively low resistance state and the relatively high resistance state. The distinct resistance states of the resistive-switching memory cell represent distinct logical information states, facilitating digital memory operations. Accordingly, the inventor(s) believe that arrays of many such memory cells, can provide many bits of digital memory storage.

The inventor(s) have been successful in inducing resistive-switching memory to enter one or another resistive state in response to an external condition. Thus, in transistor parlance, applying or removing the external condition can serve to program or de-program (e.g., erase) the memory. Moreover, depending on physical makeup and electrical arrangement, a resistive-switching memory cell can generally maintain a programmed or de-programmed state. Maintaining a state might require other conditions be met (e.g., existence of a minimum operating voltage, existence of a minimum operating temperature, and so forth), or no conditions be met, depending on the characteristics of a memory cell device.

The inventor(s) have put forth several proposals for practical utilization of resistive-switching technology to include transistor-based memory applications. For instance, resistive-switching elements are often theorized as viable alternatives, at least in part, to metal-oxide semiconductor (MOS) type memory transistors employed for electronic storage of digital information. Models of resistive-switching memory devices provide some potential technical advantages over non-volatile FLASH MOS type transistors.

In light of the above, the inventor(s) desire to continue developing practical utilization of resistive-switching technology.

### SUMMARY

The following presents a simplified summary of the specification in order to provide a basic understanding of some aspects of the specification. This summary is not an extensive overview of the specification. It is intended to neither identify key or critical elements of the specification nor delineate the scope of any particular embodiments of the specification, or any scope of the claims. Its purpose is to present some concepts of the specification in a simplified form as a prelude to the more detailed description that is presented in this disclosure.

Some embodiments of the subject disclosure relate to a two-terminal memory device with a switching layer having varying amounts of nitrogen content at different strata of the switching layer. The two-terminal memory device can comprise a first electrode situated in a first region of the two-terminal memory device, and a second electrode situated in a second region of the two-terminal memory device. The two-terminal memory device can further comprise a resistive switching layer with a first portion adjacent to the first region or closer to the first region than is a second portion. The second portion can be adjacent to the second region or closer to the second region than is the first portion. The resistive switching layer can comprise nitrogen (N) and silicon (Si) and can have a ratio, X, that is characterized as N/Si, that varies between the first portion and the second portion according to a determined variance.

The subject disclosure can further relate to methods of fabricating the two-terminal memory device. For example a fabrication device can form a bottom electrode of the two-terminal memory device overlying a metal layer. The fabrication device can introduce into a vacuum chamber comprising the BE, a gas mixture having a defined ratio, Y. The defined ratio, Y, can be characterized as an amount of nitrogen gas (N₂) to argon gas (Ar). The fabrication device can form, in the vacuum chamber, a resistive switching layer in response to a physical vapor deposition (PVD) sputtering process that varies Y during formation of the resistive switching layer. The fabrication device can form a top electrode of the two-terminal memory device overlying the resistive switching layer.

The following description and the drawings set forth certain illustrative aspects of the specification. These aspects are indicative, however, of but a few of the various ways in which the principles of the specification may be employed. Other advantages and novel features of the specification will become apparent from the following detailed description of the specification when considered in conjunction with the drawings.

### BRIEF DESCRIPTION OF THE DRAWINGS

Numerous aspects, embodiments, objects and advantages of the present invention will be apparent upon consideration of the following detailed description, taken in conjunction with the accompanying drawings, in which like reference characters refer to like parts throughout. In this specification, numerous specific details are set forth in order to provide a thorough understanding of this disclosure. It should be understood, however, that certain aspects of the subject disclosure may be practiced without these specific details, or with other methods, components, materials, etc. In other instances, well-known structures and devices are shown in block diagram form to facilitate describing the subject disclosure.

FIG. 1 illustrates a block diagram of an integrated circuit device that provides for forming a blocking layer that mitigates diffusion of material of a metal layer in accordance with certain embodiments of this disclosure.

FIG. 2A illustrates an example integrated circuit device that provides for forming a via in the blocking layer in accordance with certain embodiments of this disclosure.

FIG. 2B illustrates an example integrated circuit device illustrating formation of a bottom electrode in the via in accordance with certain embodiments of this disclosure.

FIG. 3 depicts a block diagram of an example integrated circuit device that provides for formation of a stack of layers overlying the bottom electrode in accordance with certain embodiments of this disclosure.

FIG. 4 depicts a block diagram representing an exploded view of an example two-terminal resistive switching device having variable nitrogen content in accordance with certain embodiments of this disclosure.

FIGS. 5A-D illustrate various example switching layers that illustrate non-limiting examples of nitrogen content being variable throughout the strata of the respective switching layer according to a smooth gradient function in accordance with certain embodiments of this disclosure.

FIGS. 6A-D illustrate various example switching layers that illustrate non-limiting examples of nitrogen content being variable by discrete amounts per sub-layer of the respective switching layer in accordance with certain embodiments of this disclosure.

FIG. 7 depicts a block diagram of an example deposition for a resistive switching device with gradient nitrogen composition, in further embodiments.

FIGS. 8A-8E illustrate block diagrams of a sample nitrogen concentration profile for an active metal portion of the resistive switching device, in an embodiment(s).

FIGS. 9A-9F depict block diagrams of a sample nitrogen concentration for an active metal portion and top electrode portion in an alternative embodiment(s).

FIG. 10 illustrates an example methodology that can provide for fabrication of a two-terminal memory device that varies a gas mixture during fabrication of the switching layer in accordance with certain embodiments of this disclosure.

FIG. 11 illustrates an example methodology that can provide for selecting a type of PVD sputtering and a type of variance of Y in accordance with certain embodiments of this disclosure.

FIG. 12 illustrates an example method for varying a gas mixture during fabrication of a switching layer of a resistive switching device, in further embodiments.

FIG. 13 depicts a sample method for forming a resistive switching device with gradient nitrogen concentration, in further embodiments disclosed herein.

FIG. 14 illustrates a block diagram of an example electronic operating environment in accordance with certain embodiments of this disclosure.

FIG. 15 illustrates a block diagram of an example computing environment in accordance with certain embodiments of this disclosure.

### DETAILED DESCRIPTION

### Introduction to Two-Terminal Memory

This disclosure relates to memory devices employed for digital or multi-level information storage, and processes involved in fabricating memory devices. In some embodiments, a two-terminal memory cell can be constructed at least in part according to a process disclosed herein. As an example, the two-terminal memory cell can include a resistive technology, such as a resistive-switching two-terminal cell. Resistive-switching two-terminal cells (also referred to as two-terminal resistive switching cells, two-terminal resistive switching devices, or resistive-switching memory cells or devices, among others) can comprise circuit components having conductive contacts (e.g., electrodes or terminals) with an active region between the two conductive contacts.

In some embodiments, the subject disclosure relates to a two-terminal resistive switching device with a switching layer having varying amounts of nitrogen content at different strata of the switching layer. The two-terminal memory device can further comprise a resistive switching layer. The resistive switching layer can comprise nitrogen and silicon and can have a ratio of nitrogen to silicon that varies through a thickness of the resistive switching layer according to a determined variance.

In further embodiments, the subject disclosure relates to a two-terminal resistive switching device that includes a switching layer, an active layer (also referred to as a particle donor layer) overlying the switching layer and a top electrode overlying the active layer. The active layer can comprise a compound or mixture of metal and nitrogen, and the relative concentration of the metal and nitrogen can vary through the active layer. In an embodiment, the top electrode can comprise a second metal and nitrogen material and a relative concentration of the second metal and nitrogen material can be non-uniform within the top electrode.

Herein, the terms “electrode” and “terminal” are used interchangeably; moreover, a two-terminal resistive switching device includes a non-volatile two-terminal memory device as well as a volatile two-terminal switching device. Generally, a first electrode of a two-terminal resistive switching device is referred to as a “top electrode” (TE) and a second electrode of the two-terminal resistive switching device is referred to as a “bottom electrode” (BE), although it is understood that electrodes of two-terminal resistive switching devices can be according to any suitable arrangement, including a horizontal arrangement in which components of a memory cell are (substantially) side-by-side rather than overlying one another. Between the TE and BE of a two-terminal resistive switching device is typically an interface layer sometimes referred to as a switching layer, a resistive switching medium (RSM) or a resistive switching layer (RSL); such devices are not limited to these layers, however, as one or more barrier layer(s), adhesion layer(s), ion conduction layer(s), seed layer(s), particle source layer(s) or the like—as disclosed herein, disclosed within a publication incorporated by reference herein, as generally understood and utilized in the art or reasonably conveyed to one of ordinary skill in the art by way of the context provided herein and its addition to the general understanding in the art or the incorporated publications—may be included between or adjacent one or more of the TE, the BE or the interface layer consistent with suitable operation of such device.

The interface layer of the two-terminal resistive switching device, in the context of resistive-switching memory, exhibits a plurality of stable or semi-stable resistive states, each resistive state having a distinct electrical resistance. Moreover, respective ones of the plurality of states can be formed or activated in response to a suitable electrical signal applied at the two conductive contacts. The suitable electrical signal can be a voltage value, a current value, a voltage or current polarity, or the like, or a suitable combination thereof. Examples of a resistive switching two-terminal memory device, though not exhaustive, can include a resistive random access memory (RRAM), a phase change RAM (PCRAM) and a magnetic RAM (MRAM).

Embodiments of the subject disclosure can provide a filamentary-based memory cell. In some embodiments, the filamentary-based memory cell includes a non-volatile memory device, whereas other embodiments provide a volatile selector device, and yet other embodiments provide the volatile selector device in electrical series with the non-volatile memory device. In further embodiments, both the volatile selector device and the non-volatile memory device can be filamentary-based devices, though the subject disclosure is not limited to these embodiments.

Composition of two-terminal resistive switching cells, generally speaking, can vary per device with different components, materials or deposition processes selected to achieve desired characteristics (e.g., stoichiometry/non-stoichiometry, volatility/non-volatility, on/off current ratio, switching time, read time, memory durability, program/erase cycle, and so on). One example of a filamentary-based device can comprise: a conductive layer, e.g., metal, metal-alloy, metal-nitride, (e.g., comprising TiN, TaN, TiW, or other suitable metal compounds), an optional interface boundary layer (e.g., doped p-type (or n-type) silicon (Si) bearing layer (e.g., a p-type or n-type Si bearing layer, p-type or n-type polysilicon, p-type or n-type polycrystalline SiGe, etc.)), a resistive switching layer (RSL) and an active metal-containing layer capable of being ionized. Under suitable conditions, the active metal-containing layer can provide filament-forming ions to the RSL. In such embodiments, a conductive filament (e.g., formed by the ions) can facilitate electrical conductivity through at least a subset of the RSL, and a resistance of the filament-based device can be determined, as one example, by a tunneling resistance between the filament and the conductive layer. A memory cell having such characteristics may be described as a filamentary-based device.

A RSL in a filamentary device (which can also be referred to in the art as a resistive switching media (RSM), interface layer, active region or the like) can comprise, e.g., an undoped amorphous Si-containing layer, a semiconductor layer having intrinsic characteristics, a stoichiometric or non-stoichiometric silicon nitride (e.g., SiN, Si₃N₄, SiNₓ, etc.), a Si sub-oxide (e.g., SiOₓ wherein x has a value between 0.1 and 2), a Si sub-nitride, a metal oxide, a metal nitride, a non-stoichiometric silicon compound, and so forth. Other examples of materials suitable for the RSL could include SiₓGe_{y}O_{z} (where x, y and z are respective suitable positive numbers), a silicon oxide (e.g., SiON, where N is a suitable positive number), a silicon oxynitride, an undoped amorphous Si (a-Si), amorphous SiGe (a-SiGe), TaOB (where B is a suitable positive number), HfOc (where C is a suitable positive number), TiOD (where D is a suitable number), AWE (where E is a suitable positive number) and so forth, a nitride (e.g., AlN, SiN), or a suitable combination thereof.

In some embodiments, a RSL employed as part of a non-volatile memory device (non-volatile RSL) can include a relatively large number (e.g., compared to a volatile selector device) of material voids or defects to trap neutral metal particles (e.g., at low voltage) within the RSL. The large number of voids or defects can facilitate formation of a thick, stable structure of the neutral metal particles. In such a structure, these trapped particles can maintain the non-volatile memory device in a low resistance state in the absence of an external stimulus (e.g., electrical power), thereby achieving non-volatile operation. In other embodiments, a RSL employed for a volatile selector device (volatile RSL) can have very few material voids or defects for trapping particles. Because of the few particle-trapping voids/defects, a conductive filament formed in such an RSL can be quite thin (e.g., one to a few particles wide depending on field strength, particle material or RSL material, or a suitable combination of the foregoing), and unstable absent a suitably high external stimulus (e.g., an electric field, voltage, current, joule heating, or a suitable combination thereof). Moreover, the particles can be selected to have high surface energy, and good diffusivity within the RSL. This leads to a conductive filament that can form rapidly in response to a suitable stimulus, but also deform quite readily, e.g., in response to the external stimulus dropping below a deformation magnitude (which can be lower than a formation magnitude of the external stimulus associated with forming the volatile conductive filament, e.g., in response to a current flowing through the selector device; see U.S. Pat. No. 9,633,724 B2 hereby incorporated by reference herein in its entirety and for all purposes). Note that a volatile RSL and conductive filament for the selector device can have different electrical characteristics than a conductive filament and non-volatile RSL for the non-volatile memory device. For instance, the selector device RSL can have higher material electrical resistance, and can have higher on/off current ratio, among others.

An active metal-containing layer for a filamentary-based memory cell can include, among others: silver (Ag), gold (Au), titanium (Ti), titanium-nitride (TiN) or other suitable compounds or non-stoichiometric mixtures of titanium, nickel (Ni), copper (Cu), aluminum (Al), chromium (Cr), tantalum (Ta), iron (Fe), manganese (Mn), tungsten (W), vanadium (V), cobalt (Co), platinum (Pt), hafnium (Hf), and palladium (Pd). Other suitable conductive materials, as well as stoichiometric or non-stoichiometric: compounds, nitrides, oxides, alloys, mixtures or combinations of the foregoing or similar materials can be employed for the active metal-containing layer in some aspects of the subject disclosure. Further, a non-stoichiometric compound or mixture, such as a non-stoichiometric metal oxide/metal-oxygen or metal nitride/metal nitrogen (e.g., AlOₓ, AlNₓ, CuOₓ, CuNₓ, AgOₓ, AgNₓ, and so forth, where x is a suitable positive number or range of numbers, such as: 0<x<2, 0<x<3, 0<x<4 or other number/range of numbers depending on the metal in question, which can have differing values for differing ones of the non-stoichiometric compounds/mixtures) or other suitable metal compound/mixture can be employed for the active metal-containing layer, in at least one embodiment.

In one or more embodiments, a disclosed filamentary resistive switching device can include an active metal layer comprising a metal-nitrogen selected from the group consisting of: TiNₓ, TaNₓ, AlNₓ, CuNₓ, WNₓ and AgNₓ, where x is a positive number (or range of numbers) that can vary per metal-nitrogen material. In a further embodiment(s), the active metal layer can comprise a metal-oxygen selected from the group consisting of: TiOₓ, TaOₓ, AlOₓ, CuOₓ, WOₓ and AgOₓ where x is a positive number (or range of numbers, which can be different from those utilized with nitrogen above) that can likewise vary per metal-oxygen material. In yet another embodiment(s), the active metal layer can comprise a metal oxygen-nitrogen selected from the group consisting of: TiOₐN_{b}, AlOₐN_{b}, CuOₐN_{b}, WOₐN_{b} and AgOₐN_{b}, where a and b are suitable positive numbers/ranges of numbers. The disclosed filamentary resistive switching device can further comprise a switching layer comprising a switching material selected from the group consisting of: SiO_{y}, AlN_{y}, TiO_{y}, TaO_{y}, AlO_{y}, CuO_{y}, TiNₓ, TiN_{y}, TaNₓ, TaN_{y}, SiOₓ, SiN_{y}, AlNₓ, CuNₓ, CuN_{y}, AgNₓ, AgN_{y}, TiOₓ, TaOₓ, AlOₓ, CuOₓ, AgOₓ, and AgO_{y}, where x and y are positive numbers (or ranges), and y is larger than x. Various combinations of the above are envisioned and contemplated within the scope of embodiments of the present invention.

In one example, a disclosed filamentary resistive switching device comprises a particle donor layer (e.g., the active metal-containing layer) comprising a stoichiometric or non-stoichiometric metal compound (or mixture) and a resistive switching layer. In one alternative embodiment of this example, the particle donor layer comprises a metal-nitrogen: MNₓ, e.g., AgNₓ, TiNₓ, AlNₓ, etc., and the resistive switching layer comprises a metal-nitrogen: MN_{y}, e.g., AgN_{y}, TiN_{y}, AlN_{y}, and so forth, where y and x are positive numbers (or ranges), and in some cases y is larger than x. In an alternative embodiment of this example, the particle donor layer comprises a metal-oxygen: MOₓ, e.g., AgOₓ, TiOₓ, AlOₓ, and so on, and the resistive switching layer comprises a metal-oxygen: MO_{y}, e.g., AgO_{y}, TiO_{y}, AlO_{y}, or the like, where y and x are positive numbers (or ranges), and in some cases y is larger than x. In yet another alternative, the metal compound of the particle donor layer is a MNₓ (e.g., AgNₓ, TiNₓ, AlNₓ, etc.), and the resistive switching layer is selected from a group consisting of MO_{y} (e.g., AgO_{y}, TiO_{y}, AlO_{y}, etc.) and SiO_{y}, where x and y are typically non-stoichiometric values, or vice versa (e.g., the particle donor layer is a metal-oxygen: MOₓ material and the resistive switching layer is a metal-nitrogen: MN_{y} material, where x and y are typically non-stoichiometric values) in a still further embodiment.

As utilized herein, variables x, y, a, b, and so forth representative of values or ratios of one element with respect to another (or others) in a compound or mixture can have different values (or ranges) suitable for respective compounds/mixtures, and are not intended to denote a same or similar value or ratio among the compounds. Mixtures can refer to non-stoichiometric materials with free elements therein—such as metal-rich nitride or oxide (metal-oxide/nitride with free metal atoms), metal-poor nitride or oxide (metal-oxide/nitride with free oxygen/nitrogen atoms)—as well as other combinations of elements that do not form traditional stoichiometric compounds as understood in the art. Some details pertaining to embodiments of the subject disclosure can be found in the following U.S. patent applications that are licensed to the assignee of the present application for patent: application Ser. No. 11/875,541 filed Oct. 19, 2007 and application Ser. No. 12/575,921 filed Oct. 8, 2009; each of the foregoing patent applications are hereby incorporated by reference herein in their respective entireties and for all purposes in addition to those incorporated by reference elsewhere herein.

It should be appreciated that various embodiments herein may utilize a variety of memory cell technologies, having different physical properties. For instance, different resistive-switching memory cell technologies can have different discrete programmable resistances, different associated program/erase voltages, as well as other differentiating characteristics. For instance, various embodiments of the subject disclosure can employ a bipolar switching device that exhibits a first switching response (e.g., programming to one of a set of program states) to an electrical signal of a first polarity and a second switching response (e.g., erasing to an erase state) to the electrical signal having a second polarity. The bipolar switching device is contrasted, for instance, with a unipolar device that exhibits both the first switching response (e.g., programming) and the second switching response (e.g., erasing) in response to electrical signals having the same polarity and different magnitudes.

In various embodiments, filamentary-based resistance switching devices can operate in a bipolar fashion, behaving differently in response to different polarity (or direction, energy flow, energy source orientation, etc.) external stimuli. For the volatile filamentary-based selector device, as an illustrative example, in response to a first polarity stimulus exceeding a first threshold voltage (or set of voltages), the filamentary selector device can change to a second resistance state from a first resistance state. Moreover, in response to a second polarity stimulus exceeding a second threshold voltage(s), the filamentary selector device can change to a third state from the first state. In some embodiments, the third state can be substantially the same as the first state, having the same or similar measurably distinct characteristic (e.g., electrical conductivity, and so forth), having the same or similar magnitude of threshold stimulus (though of opposite polarity or direction), or the like. In other embodiments, the third state can be distinct from the second state, either in terms of the measurable characteristic (e.g., different electrically conductivity value in response to the reverse polarity as compared to the forward polarity) or in terms of threshold stimulus associated with transitioning out of the first state (e.g., a different magnitude of positive voltage required to transition to the second state, compared to a magnitude of negative voltage required to transition to the third state).

For bipolar operation of a non-volatile filamentary-based memory cell, a conductive path or a filament forms through a non-volatile RSL in response to a suitable program voltage applied across the memory cell. In particular, upon application of a programming voltage, metallic ions are generated from the active metal-containing layer and migrate into the non-volatile RSL layer. The metallic ions can occupy voids or defect sites within the non-volatile RSL layer. In some embodiments, upon removal of the bias voltage, the metallic ions become neutral metal particles and remain trapped in voids or defects of the non-volatile RSL layer. When sufficient particles become trapped, a filament is formed and the memory cell switches from a relatively high resistive state, to a relatively low resistive state. More specifically, the trapped metal particles provide the conductive path or filament through the non-volatile RSL layer, and the resistance is typically determined by a tunneling resistance through the non-volatile RSL layer. In some resistive-switching devices, an erase process can be implemented to deform the conductive filament, at least in part, causing the memory cell to return to the high resistive state from the low resistive state. More specifically, upon application of an erase bias voltage, the metallic particles trapped in voids or defects of the non-volatile RSL become mobile ions and migrate back towards the active metal layer. This change of state, in the context of memory, can be associated with respective states of a binary bit. For an array of multiple memory cells, a word(s), byte(s), page(s), block(s), etc., of memory cells can be programmed or erased to represent zeroes or ones of binary information, and by retaining those states over time in effect storing the binary information. In various embodiments, multi-level information (e.g., multiple bits) may be stored in such memory cells.

Where no specific memory cell technology or program/erase voltage is specified for the various aspects and embodiments herein, it is intended that such aspects and embodiments incorporate any suitable memory cell technology and be operated by program/erase voltages appropriate to that technology, as would be known by one of ordinary skill in the art or made known to one of ordinary skill by way of the context provided herein. It should be appreciated further that where substituting a different memory cell technology would require circuit modifications that would be known to one of ordinary skill in the art, or changes to operating signal levels that would be known to one of such skill, embodiments comprising the substituted memory cell technology(ies) or signal level changes are considered within the scope of the subject disclosure.

As mentioned above, applying a program voltage (also referred to as a “program pulse”) to one of the electrodes of the two-terminal memory can cause a conductive filament to form in an interface layer (e.g., a RSL). By convention and as generally described herein, the TE receives the program pulse and the BE is grounded (or held at lower voltage or opposite polarity compared to the program pulse), but such is not intended to be limiting for all embodiments. Conversely, applying an “erase pulse” to one of the electrodes (generally a pulse of opposite polarity as the program pulse or to the opposite electrode as the program pulse) can break continuity of the filament, e.g., by driving the metal particles or other material that forms the filament back toward the active metal source, by dispersing metal particles within the interface layer such that electrical continuity between particles is suitably broken, or the like, or a combination of such mechanisms. Properties of this conductive filament as well as its presence or absence affect the electrical characteristics of the two-terminal memory cell such as, for example, lowering the resistance and/or increasing conductance across the two terminals when the conductive filament is present as opposed to when not present.

Following program or erase pulses, a read pulse can be asserted. This read pulse is typically lower in magnitude relative to program or erase pulses and typically insufficient to affect the conductive filament and/or change the state of the two-terminal memory cell. By applying a read pulse to one of the electrodes of the two-terminal memory, a measured current (e.g., Ion) when compared to a predetermined threshold current can be indicative of the conductive state of the two-terminal memory cell. The threshold current can be preset based on expected current values in different states (e.g., high resistance state current; respective currents of one or more low resistance states, and so forth) of the two-terminal memory device, suitable for a given two-terminal memory technology. For example, when the conductive filament has been formed (e.g., in response to application of a program pulse), the conductance of the cell is greater than otherwise and the measured current (e.g., Ion) reading in response to the read pulse will be greater. On the other hand, when the conductive filament is removed (e.g., in response to application of an erase pulse), the resistance of the cell is high because the interface layer has a relatively high electrical resistance, so the conductance of the cell is lower and the measured current (e.g., I_{off}) reading in response to the read pulse will be lower. By convention, when the conductive filament is formed, the memory cell is said to be in the “on-state” with a high conductance. When the conductive filament is not extant, the memory cell is said to be in the “off-state”. A memory cell being in the on-state or the off-state can be logically mapped to binary values such as, e.g., “1” and “0”. It is understood that conventions used herein associated with the state of the cell or the associated logical binary mapping are not intended to be limiting, as other conventions, including an opposite convention can be employed in connection with the disclosed subject matter. Techniques detailed herein are described and illustrated in connection with single-level cell (SLC) memory, but it is understood that the disclosed techniques can also be utilized for multi-level cell (MLC) memory in which a single memory cell can retain a set of measurably distinct states that represent multiple bits of information.

By mapping digital information to non-volatile resistance states of a two-terminal memory cell, digital information can be stored at such device. An electronic device containing many of these two-terminal memory cells can likewise store significant quantities of data. High density arrays are configured to contain as many memory cells as possible for a given area of chip space, thereby maximizing data storage capacity of a memory chip, or system-on-chip device.

For two-terminal memory formed at intersections of metal lines within a wafer (e.g., a crossbar array), two general conventions for arrangement of the memory cells are considered. A first convention is the 1T1R memory array, in which each memory cell is isolated from electrical effects (e.g., current, including leak path current(s)) of surrounding circuitry by an associated transistor. A second convention is the 1TnR memory array (n being a positive number greater than one), where a group of multiple memory cells is isolated from electrical effects of surrounding circuitry by one (or more) transistors. In the 1T1R context, individual memory cells can be configured to have high current suppression between memory cells, significantly reducing leakage path currents for the 1T1R memory array. In the 1TnR context, many individual memory cells having high device density in a given amount of silicon space can be connected to a single transistor that has much lower density. Accordingly, the 1TnR context facilitates higher bit densities for resistive memory cells on a semiconductor chip.

One example mechanism for connecting a 1T1R memory array includes a first terminal of a two-terminal resistive memory device connected to a drain of a transistor. A second terminal of the two-terminal resistive memory device can be connected to a bitline of the 1T1R memory array. The source of the transistor is grounded or used as a source for erase or program signals, depending on erase/programming conditions for the memory array. Another example mechanism involves a three-terminal memory including a transistor coupled to a volatile two-terminal resistive switching device. A first terminal of the volatile RSD is connected to a gate of the transistor, and a second terminal of the volatile RSD is connected to a voltage source. When activated, the volatile RSD permits charge to accumulate at the gate of the transistor, and when deactivated can trap that accumulated charge at the transistor gate. Other resistive switching device (RSD) circuits can be utilized within the scope of the present disclosure.

### General Overview

Two-terminal resistive switching devices such as two-terminal memory and two-terminal selector device can have a resistive switching layer (AKA an interface layer) in which a filament forms and deforms in response to electrical stimuli. Filament formation and deformation (e.g., retreating back to the active metal layer; breaking electrical continuity, etc.) changes the electrical properties of the device and the various electrical states of the device can be mapped to logical data values. In some embodiments, the properties of the resistive switching layer generally benefit from being tightly controlled on the one hand, but on the other hand, the resistive switching layer can be somewhat delicate. Stresses and extreme conditions that occur during the fabrication process can negatively impact various properties of the resistive switching layer, which can in turn affect the properties of the two-terminal resistive switching device. Examples can include properties such as program voltage, erase voltage, memory endurance, memory retention, leakage characteristics and so forth.

Various embodiments of the present disclosure provide for utilizing one or more nitrogen compounds or mixtures as the resistive switching layer or an active metal layer (e.g., a particle donor layer) and associated advantages. In other embodiments, utilizing one or more oxygen compounds or mixtures as the resistive switching layer can be advantageous. As some examples, silicon-nitrogen films (e.g., a layer or layers), metal-nitrogen films, or metal-oxygen films utilized as the resistive switching layer can be advantageous. Still further, for nitrogen compounds or mixtures, by varying the nitrogen content in these one or more films, numerous advantages can be achieved. For example, a silicon-nitrogen film can have much better contact control. Moreover, the silicon-nitrogen film can be much more stable than other switching layer compositions or fabrication techniques. Such can make the film less likely to be altered in an undesired way during the device fabrication processes or allow a higher thermal budget during the fabrication processes. Hence, the properties of the device can be more tightly controlled, can be more uniform, or have less variance in performance. In other embodiments, a metal-nitrogen film(s) can have varying percentage of nitrogen through a thickness of the film (or from film to film in a multi-film layer). The varying percentage of nitrogen through the thickness of the film can be utilized to achieve a target contact resistance between layers, achieve a high degree of control over nitrogen concentration at a boundary with another nitrogen-based layer, achieve a target minimum electrical resistance for the layer, achieve a target free metal concentration, promote thermal stability of metal material, promote adhesion between the film and other layers, or the like, or a suitable combination of the foregoing.

In order to fabricate disclosed silicon-nitrogen film(s) with some or all desired properties noted herein or other beneficial properties, the disclosure further provides various techniques of modulating gas flow in a vacuum chamber to produce disclosed resistive switching layers. For example, provided are techniques of using physical vapor deposition (PVD) which is not limited to one or the other of direct current (DC) sputtering and radio frequency (RF) sputtering. Rather, either or both DC sputtering or RF sputtering can be employed. It is understood that, conventionally DC sputtering is typically used in connection with forming films comprising metals or other conductive materials, whereas RF sputtering is typically used in connection with forming films comprising insulators. Hence, previous systems select one or the other, but typically do not have the capacity to utilize either or both DC sputtering and RF sputtering.

In some embodiments, a disclosed film(s) can be fabricated by modulating the gas flow in a manner that varies the proportion of nitrogen gas to argon gas, modulating power applied to a sputtering target, modulating temperature or pressure within a deposition chamber, or the like or suitable combinations of the foregoing. In some embodiments, the film(s) can be deposited in the same vacuum chamber or with the same fabrication tool without breaking the vacuum. Such can avoid undesired contamination and other composition control issues.

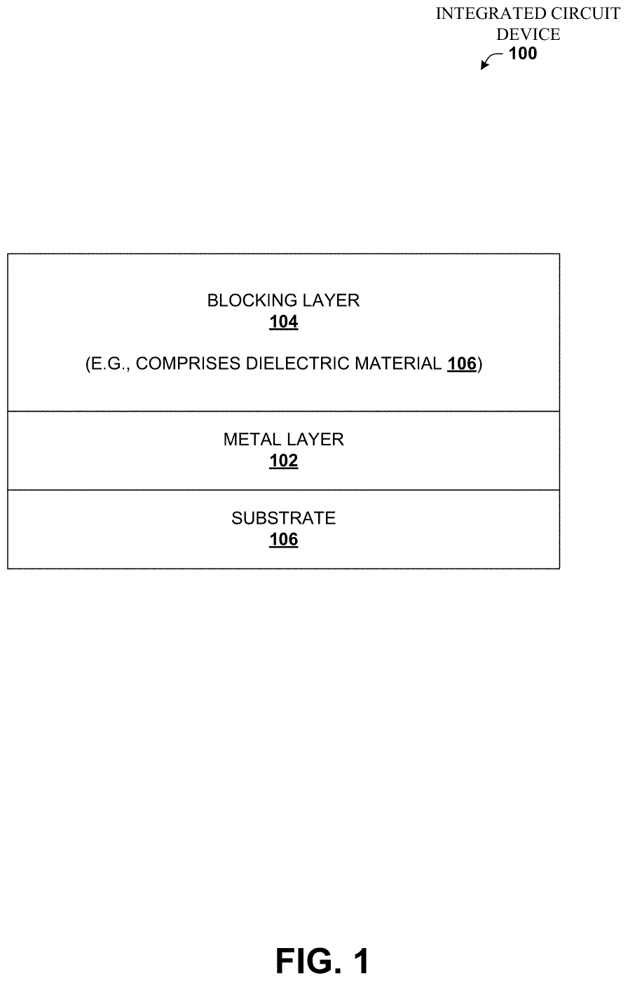

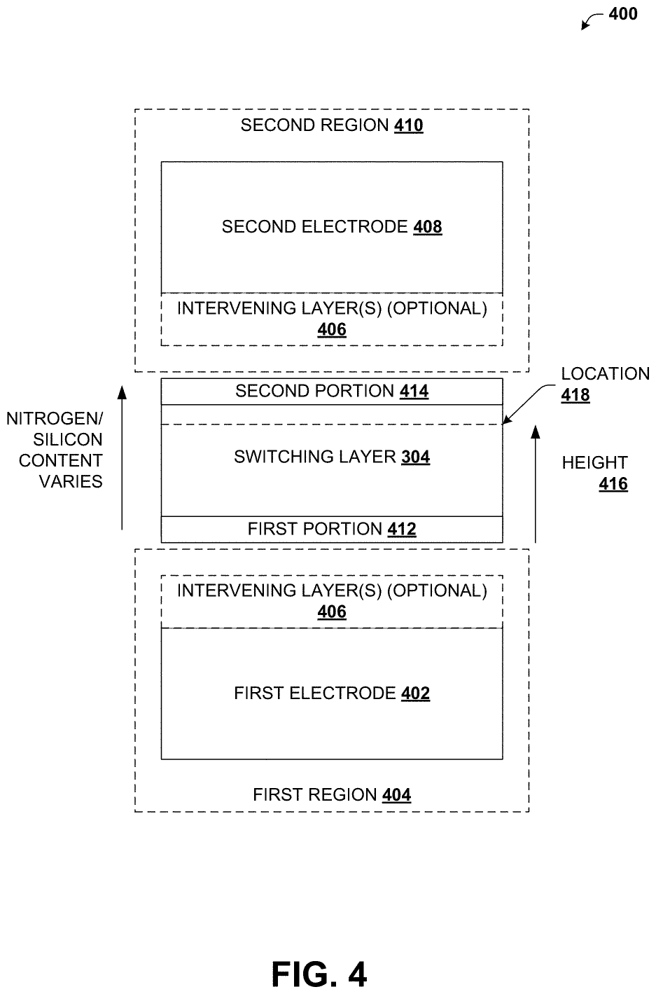

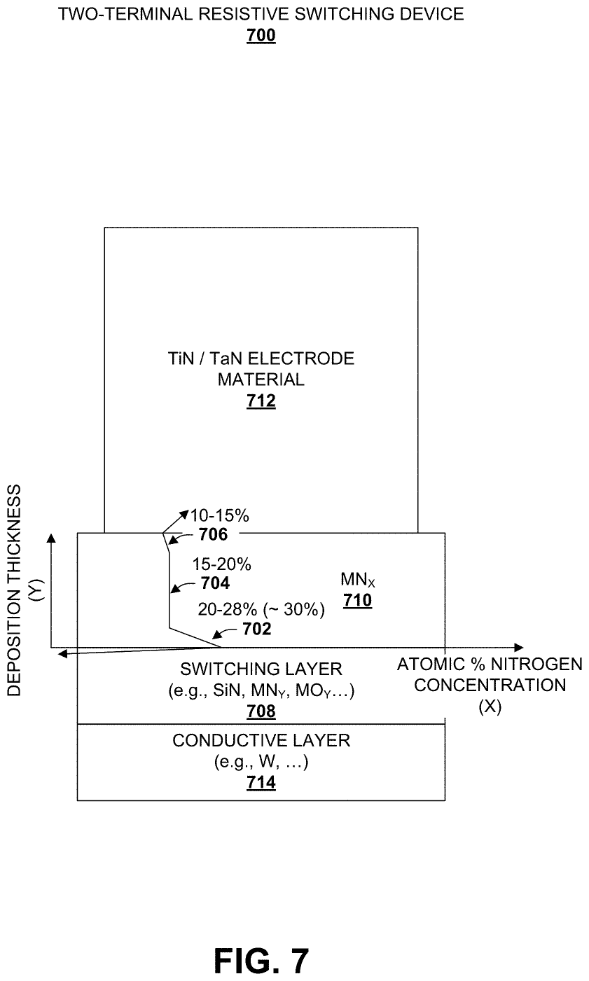

In the description below, FIGS. 4-6D relate to various example configurations of the resistive switching layer, which can be a single film or can have multiple films (e.g., sub-layers). FIGS. 7-9 relate to various example techniques for fabricating the resistive switching layer. FIGS. 1-3 relate to various two-terminal memory device configurations in which the disclosed resistive switching layer is compatible. Accordingly, it is understood that FIGS. 1-3 represent non-limiting examples of the overall device and it is appreciated that the resistive switching layer can be employed in other devices with different configurations.

### Example Embodiments

Various aspects or features of this disclosure are described with reference to the drawings, wherein like reference numerals are used to refer to like elements throughout. In this specification, numerous specific details are set forth in order to provide a thorough understanding of this disclosure. It should be understood, however, that certain aspects of disclosure may be practiced without these specific details, or with other methods, components, materials, etc. In other instances, well-known structures and devices are shown in block diagram form to facilitate describing the subject disclosure.

Referring initially to FIG. 1, integrated circuit device 100 is depicted that illustrates a blocking layer that, as one example function, mitigates diffusion of material of a metal layer for integrated circuit device 100, or in conjunction with integrated circuit fabrication techniques. For instance, blocking layer 104 can be formed overlying metal layer 102 of a two-terminal memory device. Metal layer 102 can be a diffusive metal, metal alloy or metal compound in various embodiments. As an illustrative case, metal layer 102 can be, e.g., copper (Cu) or another suitable material. In some embodiments, metal layer 102 can be a bitline or a wordline of an integrated circuit memory array, whereas in other embodiments metal layer 102 can be local to integrated circuit device 100, or local to a subset of the integrated circuit memory array.

Blocking layer 104 can comprises dielectric material 106. Dielectric material 106 can be a material selected to mitigate diffusion of the diffusive metal material such as copper or another diffusive material of metal layer 102. Dielectric material 106 can be referred to herein as blocking layer 104 and/or can represent a portion of a blocking layer 104. In some embodiments, dielectric material 106 can comprise nitrogen doped carbide (NDC), SiN, a silicon carbide compound, SiCN, SiON, an amorphous silicon, or the like. In some embodiments, dielectric material 106 is a single layer, while in other embodiments, dielectric material 106 comprises multiple layers of different materials.

In some embodiments, metal layer 102 can be formed on or overly substrate 106. In some embodiments, intervening layers (not shown) can be formed between metal layer 102 and substrate 106. In some embodiments, metal layer 102 and blocking layer 104 can be formed in front-end-of-line processing layers over substrate 106 and/or over one or more optional intervening layers. In some embodiments, metal layer 102 and blocking layer 104 can be formed in back-end-of-line processing layers over substrate 106 and/or one or more intervening layers. In some embodiments, metal layer 102 and blocking layer 104 can be provided as part of another suitable integrated circuit fabrication process.

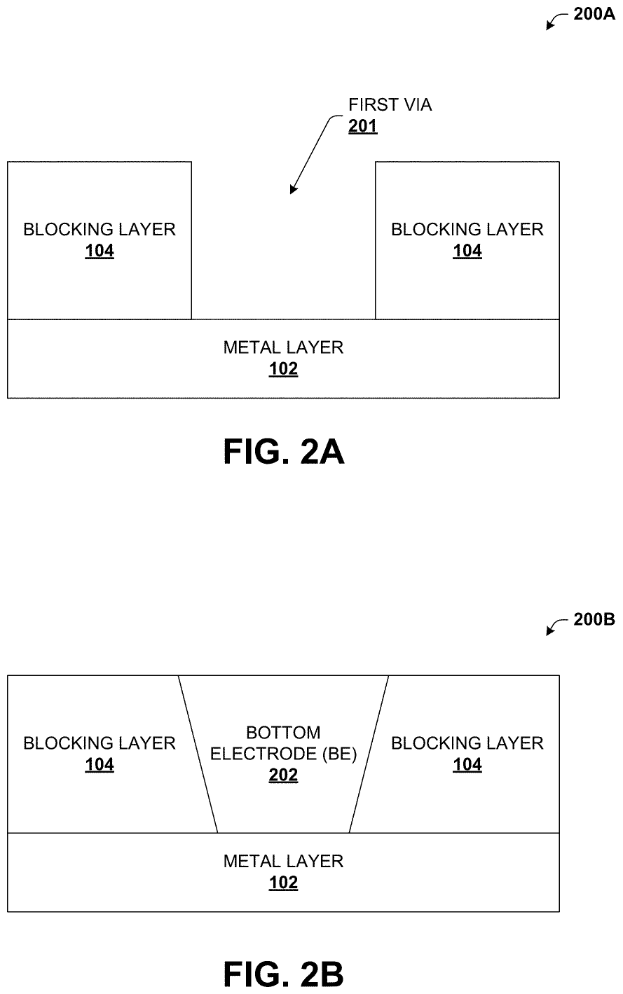

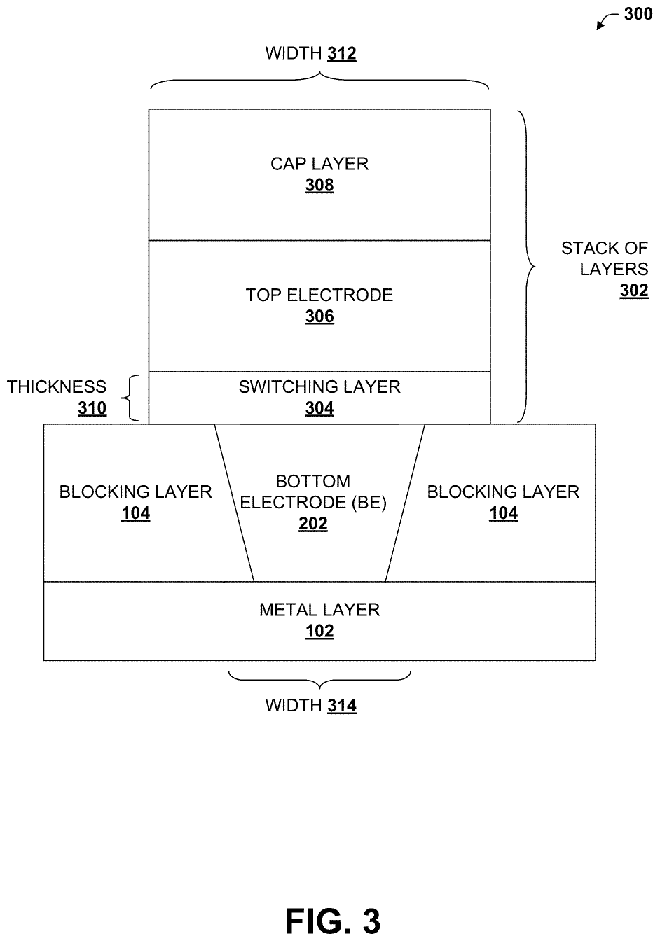

FIG. 2A depicts an integrated circuit device 200A having a first via 201 formed in the blocking layer 104 of integrated circuit device 100 in accordance with certain embodiments of this disclosure. Repetitive description of like elements employed in other embodiments described herein is omitted for sake of brevity. First via 201 can be formed in response to a pattern and etching process. Formation of first via 201 can expose a (top) surface of metal layer 102 of integrated circuit device 100. In some embodiments, sidewalls of blocking layer 104 adjacent to and exposed by via 201 can be sloped (not shown, but see FIGS. 2B and 3), rather than vertical. In other embodiments, the sidewalls of blocking layer 104 can be perpendicular or substantially perpendicular to the exposed surface of metal layer 102, as shown.

FIG. 2B depicts an integrated circuit device 200B comprising a bottom electrode formed within the first via 201 of integrated circuit device 200A of FIG. 2, supra in accordance with certain embodiments of this disclosure. Repetitive description of like elements employed in other embodiments described herein is omitted for sake of brevity. For example, bottom electrode 202 can be deposited or otherwise formed in first via 201. Bottom electrode (BE) 202 can comprise an electrical conductive material and can be in contact (e.g., electrical contact, direct contact, etc.) with metal layer 102 and adjacent portions of blocking layer 104. FIG. 2B illustrates an embodiment in which sidewalls of blocking layer 104 (and via 201) are sloped.

Turning now to FIG. 3, integrated device 300 is depicted. Integrated device 300 provides for formation of a stack of layers 302 overlying integrated device 200B, including the BE 202 in accordance with certain embodiments of this disclosure. Repetitive description of like elements employed in other embodiments described herein is omitted for sake of brevity. Stack of layers 302 and BE 202 can be formed as a pillar and collar configuration, as shown (e.g., with BE 202 serving as a relatively narrow pillar underlying stack of layers 302 which serve as a relatively wider collar of the pillar and collar configuration). Said differently, a width 314 of BE 202 can be less than a width 312 of the top electrode 306 as well as less than switching layer 304 and/or cap layer 306. In other embodiments, integrated device 300 can be formed as a monolithic stack, or any other suitable configuration. Stack of layers 302 can comprise switching layer 304, as depicted. Switching layer 304 can be overlying and in contact with BE 202 in one or more embodiments. In alternative or additional embodiments, one or more intervening layers (not shown, but see FIG. 4) can be provided between switching layer 304 and BE 202.

Stack of layers 302 can comprise top electrode (TE) 306 that can be overlying and in contact with switching layer 304 in an embodiment. In alternative or additional embodiments, one or more intervening layers can be provided between top electrode 306 and switching layer 304. Stack of layers 302 can comprise cap layer 308 that can be overlying and in contact with top electrode 306 (optionally comprising one or more suitable intervening layers). In some embodiments, cap layer 308 can comprises titanium nitride (TiN).

In some embodiments, TE 306 (or BE 202) can comprise the active metal layer. As detailed supra, the active metal layer can comprise a metal nitride such as, e.g., TiNₓ, TaNₓ, AlNₓ, CuNₓ, WNₓ and AgNₓ, where x is a positive number. In some embodiments, TE 306 (or BE 202) can comprise a metal nitride in one layer or strata of the TE 306 (or BE 202) and a metal in another layer or strata of the TE 306 (or BE 202). For example, TE 306 can comprise AlNₓ in a lower strata near to switching layer 304 and Al in an upper strata near cap layer 308.

In some embodiments, a thickness (e.g., height) 310 of switching layer 304 can be in a range of between about 1 angstroms and about 100 angstroms. In some embodiments, thickness 310 can be in a range of between about 10 angstroms and about 50 angstroms.

Referring now to FIG. 4, illustrated is an exploded view of an example two-terminal resistive switching device 400 having variable nitrogen content in accordance with certain embodiments of this disclosure. Repetitive description of like elements employed in other embodiments described herein is omitted for sake of brevity. Two-terminal resistive switching device 400 is depicted here as a monolithic stack of layers, but other configurations are possible such as a pillar and collar configuration and others. Two-terminal resistive switching device 400 can comprise a resistive switching layer (e.g., switching layer 304) in which nitrogen and/or silicon content varies according to a defined or determined variance scheme. In some embodiments, resistive switching layer 304 is configured to be non-volatile, e.g., a state of the filament does not change in the absence of power. In some embodiments, resistive switching layer 304 is configured to be volatile, e.g., the state of the filament reverts to a base state in the absence of power.

Two-terminal resistive switching device 400 can comprise a first electrode 402 that can be situated in a first region 404 of the device. Two-terminal resistive switching device 400 can comprise a second electrode 408 that can be situated in a second region 410 of the device. First and second regions 404 and 410 are depicted with broken lines and, in some embodiments (not shown) may comprise respective portions of switching layer 304. First and second regions 404 and 410 are used herein as a means of orientation and/or to better explain the disclosed subject matter.

In some embodiments, first and second regions 404 and 410 can include one or more intervening layers 406. Intervening layer(s) 406 can include one or more of a resistive switching selector device and/or a volatile-based resistive switching layer, an electrical contact layer, a diffusion blocking layer, an adhesion layer, a silicon containing layer (e.g., to control defect density of switching layer 304), or the like, or a suitable combination of the foregoing, or other suitable layers or components. While FIG. 4 represents an exploded view, it is understood that in embodiments, in which intervening layers 406 exist, switching layer 304 can be in direct physical contact with intervening layers 406. In embodiments without intervening layers 406, switching layer 304 can be in direct physical contact with first and/or second electrodes 402 and 408.

Switching layer 304 can comprise a first portion 412 that can be adjacent to first region 404 or is closer to first region 404 than second portion 414 is to first region 404. In other words, first portion 412 can be in contact with or adjacent to first electrode 402 or in contact with or adjacent to intervening layers 406, should those be extant in first region 404. Switching layer 304 can comprise a second portion 414 that can be adjacent to second region 410. In other words, second portion 414 can be in contact with or adjacent to second electrode 408 or in contact with or adjacent to intervening layers 406, should those be extant in second region 410. However, while first and second portions 412 and 414 are depicted as being on the edges of switching layer, such need not be the case in all embodiments. For example, one or both of portions 412, 414 can be more centralized in location, but in all cases portions 412, 414 can represent different strata of switching layer 304 and one of the portions (e.g., 412) is closer to one of the regions 404, 410 than is the other portion (e.g., 414) and vice versa.

In some embodiments, switching layer 304 can be composed substantially entirely of some combination of nitrogen (N) and silicon (Si). In other embodiments, switching layer 304 can comprise other suitable materials in addition to N and Si. Regardless of whether other materials are present, switching layer 304 can have a ratio referred to herein as X, that represents a ratio of N/Si (e.g., N:Si). Advantageously, the ratio, X, of switching layer 304 can vary between first portion 412 and second portion 414. As is further detailed below, the nitrogen content or X can vary at a particular location 418 or strata of switching layer 304 according to a defined or determined variance. For example, X can vary according to a smooth gradient in some embodiments, whereas in other embodiments, X can vary according to discrete step functions or similar. It is understood that the defined variance can represent an actively determined variance and therefore can be distinguished from manufacturing imprecision, defects, or contaminants, or other unintentional variances.

In some embodiments, X can vary between first portion 412 and second portion 414 in a range of between about 0 to about 1.33. In other words, 0≤X≤1.33. Thus, consider a case in which first portion 412 has a value of X₁=0 and second portion 414 has a value of X₂=1.33. In that case, first portion 412 has virtually no nitrogen content and can thus be composed entirely of silicon or a combination of silicon and other materials. Second portion 414 however has about 1.33 parts nitrogen to one part silicon and can be composed entirely of stoichiometric silicon nitride (Si₃N₄) or composed of Si₃N₄ in combination with other suitable materials. In this example, switching layer 304 can be composed of substantially pure silicon (e.g., X=0) on one side (e.g., closer to first electrode 402) and substantially pure stoichiometric silicon nitride on the other side (e.g., closer to second electrode 408) with the same or other values of X in between. First electrode 402 can be a bottom electrode (e.g., BE 202) and second electrode 408 can be a top electrode (e.g., TE 306), but the reverse convention is suitable as well.

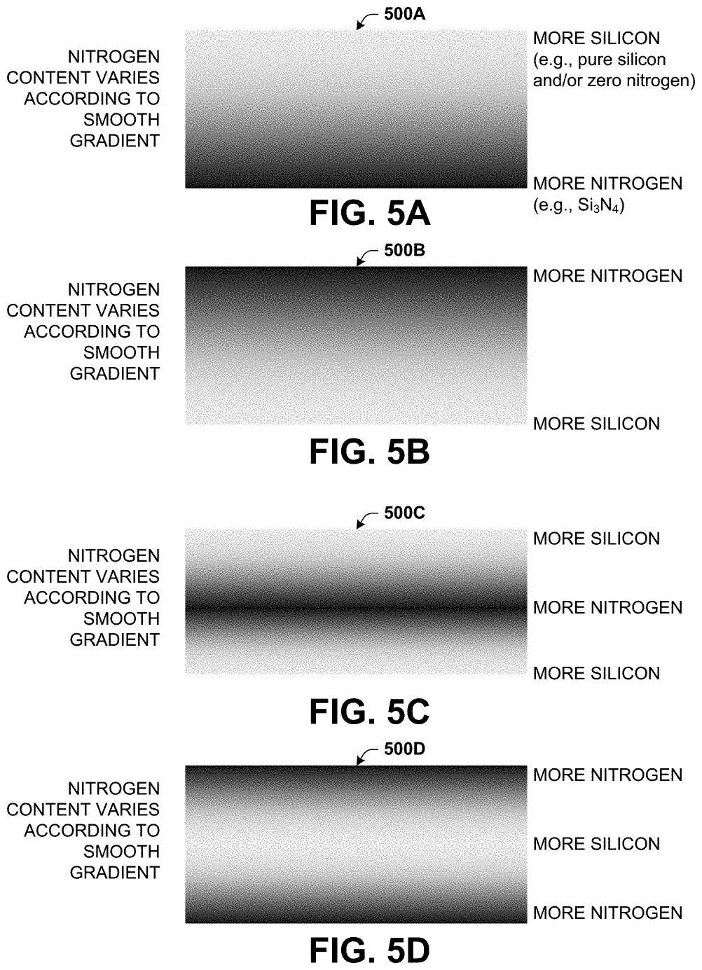

As detailed, X can vary according to a determined variance. In some embodiments, the determined variance can be representative of a gradient function that increases or decreases the ratio, X, at a particular location 418 of switching layer 304 as a function of a height 416 of the particular location 418. In some embodiments, height 416 can be bounded by thickness 310, which can be in a range of between about 1 to about 100 angstroms; or in a range of between about 10 to about 50 angstroms. In some embodiments, the determined variance can be a function of a distance from first portion 412 or second portion 414. In some embodiments, the gradient function can increase or decrease the ratio, X, as a function of another distance from first electrode 402 or second electrode 408. Various non-limiting examples of the gradient function can be found in connection with FIGS. 5A-5D.

Turning now to FIGS. 5A-5D, various example switching layers 500A-500D are depicted that illustrate non-limiting examples of nitrogen content being variable throughout the strata of the respective switching layer according to a smooth gradient function in accordance with certain embodiments of this disclosure. In the depicted examples, lighter shades or colors indicate more silicon (e.g., a lower value of X) and darker colors or shades indicate more nitrogen (e.g., a higher value of X). For example, switching layer 500A has the lower values of X (e.g., less nitrogen) at the upper portions or strata of switching layer 500A, whereas the lower portions or strata have higher values of X (e.g., more nitrogen). In some embodiments, a top surface of switching layer 500A can be composed of substantially pure silicon (e.g., zero nitrogen) and the bottom surface can be composed of substantially stoichiometric silicon nitride. Locations in between these two surfaces can vary X according to a smooth gradient, as depicted. However, it is understood that the gradient by which X is varied does not necessarily have to remain constant, but rather can be according to any suitable function.

Switching layer 500B depicts what is effectively the inverse situation as switching layer 500A, wherein the top surface has the most nitrogen content and the bottom surface has the least. Again, such can represent materials ranging from silicon at the bottom to stoichiometric silicon nitride at the top or other values of X within that range.

Switching layer 500C illustrates a configuration in which the outer edges comprise the least nitrogen and the middle regions comprising the most nitrogen. Switching layer 500D illustrates a configuration in which the middle regions comprise the least nitrogen and the upper and lower edges comprise the most nitrogen. It is understood that other configurations can be suitable, including multiple instances of the example gradient functions and combinations of the example gradient functions.

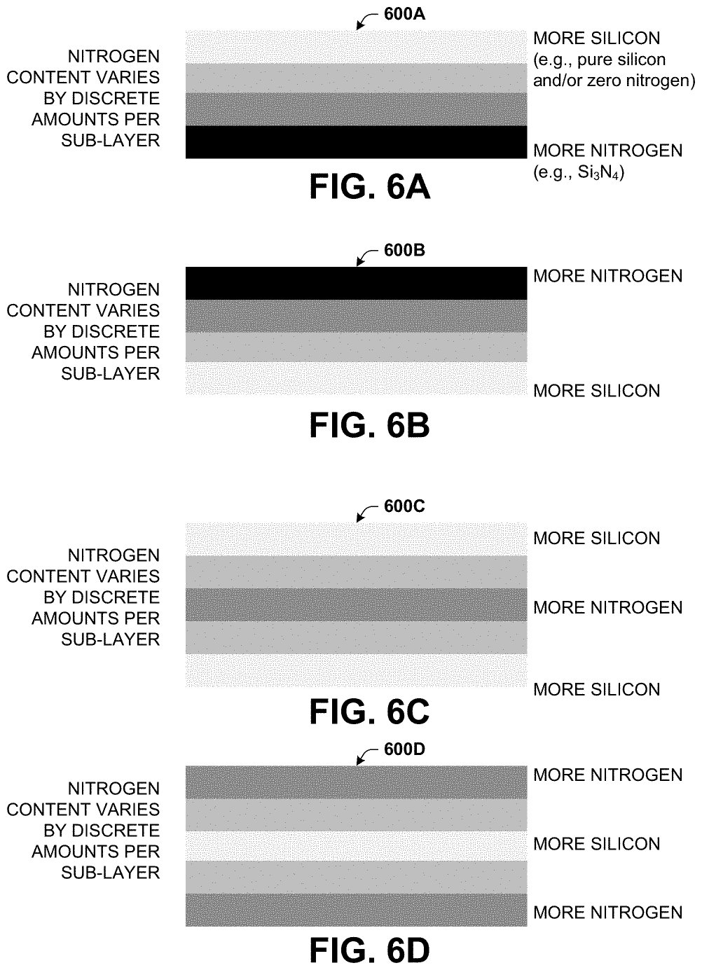

Turning now to FIGS. 6A-6D, various example switching layers 600A-600D are depicted that illustrate non-limiting examples of nitrogen content being variable by discrete amounts per sub-layer of the respective switching layer in accordance with certain embodiments of this disclosure. In the depicted examples, lighter shades or colors indicate more silicon (e.g., a lower value of X) and darker colors or shades indicate more nitrogen (e.g., a higher value of X). For example, switching layer 600A has the lower values of X (e.g., less nitrogen) at the uppermost sub-layer, whereas the lowermost sub-layer has higher values of X (e.g., more nitrogen). In some embodiments, uppermost sub-layer of switching layer 600A can be composed of substantially pure silicon (e.g., zero nitrogen) and the lowermost sub-layer can be composed of substantially stoichiometric silicon nitride. Sub-layers in between can have different values of X, as depicted.

Switching layer 600B depicts what is effectively the inverse situation as switching layer 600A, wherein the topmost sub-layer has the most nitrogen content and the bottommost sub-layer has the least. Again, such can represent materials ranging from silicon at the bottom to stoichiometric silicon nitride at the top or other values of X within that range.

Switching layer 600C illustrates a configuration in which the uppermost and lowermost sub-layers comprise the least nitrogen and the middle sub-layers comprising the more nitrogen. Switching layer 600D illustrates a configuration in which the middle sub-layers comprise less nitrogen and the upper and lower sub-layers comprise the most nitrogen. It is understood that other configurations can be suitable.

By convention herein, varying X at different strata in a smooth or gradient manner (e.g., FIGS. 5A-5D) is deemed to represent a single layer, whereas varying X by discrete amounts at different strata (e.g., FIGS. 6A-6D) is deemed to represent multiple sub-layers. Hence, switching layers 500A-500D are considered herein to be a single layer or a single film, while switching layers 600A-600D are considered to comprise multiple layers or multiple films, referred to as sub-layers. A rationale for this convention is that X can be varied by modulating gas flow in a vacuum chamber, which is further detailed in connection with FIG. 7. To provide a smooth gradient, the gas flow typically does not need to be halted. On the other hand, to vary X by discrete amounts, gas flow can be temporarily halted between each sub-layer. Thus, treating a switching layer (e.g., switching layer 304) as having a single layer as opposed to having multiple sub-layers can be based on whether gas flow was halted or substantially reduced during fabrication of the switching layer.

Hence, it is understood switching layer 500A that is treated as being composed of a single layer can be similar in thickness to switching layer 600A that is treated as being composed of many layers. As an example, both switching layers 500A and 600A can have a thickness or height in a range of between about 1 angstrom to about 100 angstroms. In other embodiments, the range can be between about 10 angstroms to about 50 angstroms. In some embodiments, individual sub-layers (e.g., of switching layers 600A-600D) can have a thickness or height in a range of between about 1 angstrom to about 5 angstroms. In some embodiments, individual sub-layers can have a thickness or height in a range of between about 2 angstroms to about 3 angstroms. It is therefore observed that in some embodiments a given switching layer can have a maximum of up to about 100 sub-layers. In other embodiments, a given switching layer can have a maximum of up to about 20-30 sub-layers.

It is further understood that the value of X within a given sub-layer can be substantially uniform in some embodiments, or put differently, the nitrogen content within the sub-layer is substantially homogeneous. In other embodiments, X can vary within the sub-layer, as one example by a gradient function such as those discussed in connection with FIGS. 5A-5D.

FIG. 7 illustrates a block diagram of an example two-terminal resistive switching device 700 having an active layer comprising a metal nitrogen material having a non-continuous nitrogen concentration. As illustrated, two-terminal resistive switching device 700 comprises an electrical conductive layer 714. Electrical conductive layer 714 can be a metal material, such as tungsten (W), titanium (Ti), a W and Ti mixture, alloy or compound, or an electrically conductive compound (e.g., nitride) of one or more of the foregoing.

A switching layer 708 is provided overlying conductive layer 714. Switching layer 708 is a relatively non-electrically conductive material (e.g., in comparison to conductive layer 714 or in comparison to TiN/TaN electrode material 712, introduced below). In an embodiment, switching layer 708 can comprise a SiN material as described herein. In other embodiments, switching layer 708 can comprise a MN_{y} material; in still other embodiments, switching layer 708 can comprise a MO_{y} material where y is a suitable value providing a non-stoichiometric relative concentration of metal to nitrogen or metal to oxygen and is selected to provide MN_{y} or MO_{y} material with a higher electrical resistance than MN, layer 710. In an embodiment, y can be selected from a value suitable to provide the relatively non-electrically conductive characteristic of switching layer 708, described above. For example, an electrical resistance of switching layer 708 can be in a range from about 50 megaohm (Mohm) to about 5 gigaohm (Gohm), or any suitable value or range there between (e.g., greater than 500 Mohm). In at least one embodiment, y can have a value in terms of relative concentration (of N or of O) greater than a value of x utilized for MN, layer 710. In various embodiments, the metal M can be Al, Cu, Ag, Ni, W, Ti or Ta. In at least one embodiment, switching layer 708 can comprise a metal oxygen-nitrogen compound or mixture MOₐN_{b} where a and b are suitable values to provide the relatively non-electrically conductive characteristic of switching layer 708.

In one or more embodiments, switching layer 708 can at least in part comprise an AlO_{y} material. The AlO_{y} material can be formed of a physical vapor deposition (PVD) process. The PVD process can employ sputtering of an Al metal target (optionally doped with 0-2% of Si, W, or a combination thereof) with a power in the range of 250 watts (W) to 5000 W (e.g., a range of 500 W to 2000 W, a range of 500 W to 1000 W, about 700 W, about 750 W, about 800 W, etc.) or any suitable value or range there between. Still further, temperature for deposition of the AlO_{y} material can be a range of about 25 degrees Celsius (C) to about 350 C (e.g., about 25 C to 300 C, about 100 C to 300 C, about 200 C, about 250 C, about 300 C, about 350 C, and so forth) or any suitable value or range there between. In addition to the foregoing, pressure for the deposition can be from about 1 milliTorr (mT) to about 10 mT, or any suitable value or range there between (e.g., 3-5 mT, 3 mT, 4 mT, 5 mT, etc.) and the deposition can occur in argon and oxygen environment with an O₂ to Ar ratio of between about 1 to 4 to about 1 to 30 (e.g., about 10 to 20; about 12 to 18; about 15, about 12, about 20, about 18, and the like) or any suitable value or range there between.

A metal nitrogen MNₓ 710 having a non-continuous nitrogen concentration is provided overlying switching layer 708. In various embodiments, metal nitrogen 710 can have a plurality of nitrogen concentration regions. In some embodiments, metal nitrogen 710 can have a first metal nitrogen region 702 having a first nitrogen concentration that is nitrogen rich. The nitrogen rich region near switching layer 708 is selected to bind metal of the metal nitrogen material resulting in reduced free metal (e.g., compared with lower non-stoichiometric concentrations), increased thermal stability (e.g., mitigating or avoiding thermal diffusion of metal into switching layer 708, and mitigating or avoiding agglomeration of the metal of the metal nitrogen material within metal nitrogen MNₓ 710) and increased chemical stability (e.g., mitigating or avoiding diffusion of metal into switching layer 708 in response to subsequent etching of a stack of layers to produce two-terminal resistive switching device 700) compared to lower nitrogen concentrations of non-stoichiometric metal nitrogen material, while still having some free metal available in response to an external stimulus (e.g., electric field, a voltage, a current, a target temperature, or the like, or a suitable combination) for drift within switching layer 708 to form a conductive filament within switching layer 708, as described herein or known in the art. The first nitrogen concentration of first metal nitrogen region 702 can have a relative atomic percentage of nitrogen to metal in a range of about 20 to about 28%, or as high as about 30% nitrogen to metal.

As utilized herein, relative terms such as “about”, “substantially” or the like when utilized in conjunction with a quantitative value or range or in conjunction with a qualitative noun or modifier refer to variations that have similar function or operational effect, are within a manufacturing tolerance generally understood by one of ordinary skill in the art (e.g., a range of values about which a mathematical value can actually be realized with fabrication equipment), or the like. As an example, about 20% nitrogen concentration in a metal nitrogen material can be a range about 20% nitrogen concentration that one of ordinary skill in the art would understand to be realizable with available fabrication equipment in the art. As another example, about 20% to about 28% can refer to numbers higher or lower than the explicit number that achieve some or all stated functions or operational effects for an associated component (e.g., an active layer of two-terminal resistive switching device 700). In the example provided for metal nitrogen MNₓ layer 710 above, about 20% to about 28% can include a range of values above or below the stated number that achieve at least one disclosed function or disclosed operational effect of an active metal material, or at least one disclosed function or operational effect of first metal nitrogen region 702. For instance: reduced free metal, increased thermal stability (e.g., reduced thermal diffusion; reduced metal agglomeration, . . . ) or reduced chemical stability (e.g., reduced chemical diffusion), while achieving drift of metal particles into switching layer 708 in response to an external stimulus.

Overlying first metal nitrogen region 702 is a second metal nitrogen region 704, and a third metal-nitrogen region 706. Second metal nitrogen region 704 can have a relative concentration of nitrogen in a second range of about 15 to about 20 percent in one or more embodiments. This second range can be selected to achieve thermal and chemical stability above a previous metal nitrogen layer (metal nitrogen region 702) while providing a larger quantity of free metal for providing filament forming particles to switching layer 708. Third metal nitrogen region 706 can have a relative concentration of nitrogen in a third range of about 10 to about 15 percent in various embodiments. The third range can be selected to be high enough to avoid metal agglomeration resulting from too high of metal concentrations, while also avoiding too much nitrogen in metal nitrogen region 706 resulting from subsequent deposition of the TiN/TaN electrode material 712. Because TiN/TaN electrode material 712 has a relatively high nitrogen concentration (e.g., about 40% in one or more embodiments), deposition of the TiN/TaN electrode material 712 can effectively increase nitrogen concentration of third metal nitrogen region 706 above that of second nitrogen region 704. Accordingly, third metal nitrogen region 706 can be intentionally nitrogen-poor as deposited, and acquire additional nitrogen upon deposition of TiN/TaN electrode material 712 resulting in increased nitrogen concentration for at least some (or all) portions of third metal nitrogen region 706. In an embodiment, the increased nitrogen concentration for third metal nitrogen region 706 can approximate or reach the about 15 to about 20 percent of second metal nitrogen region 704.

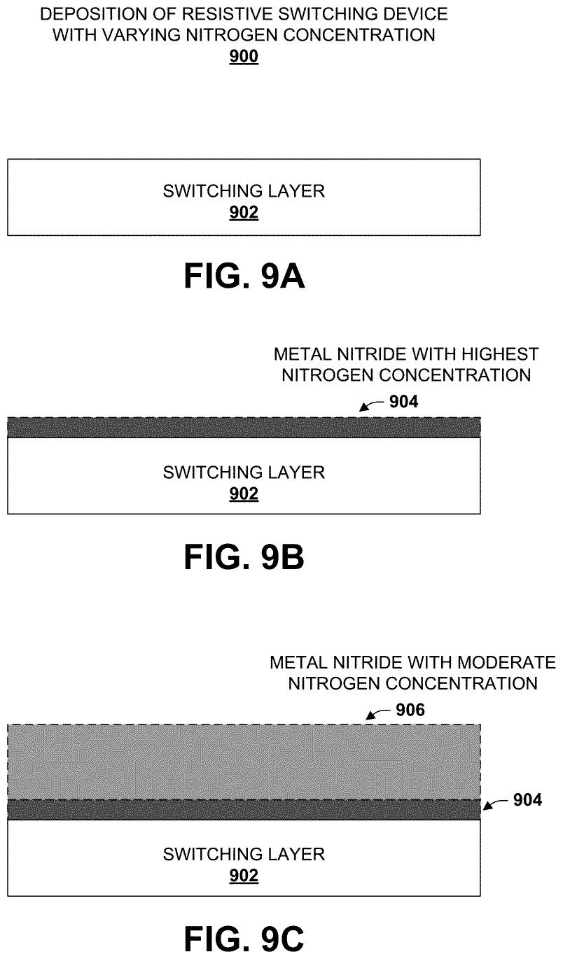

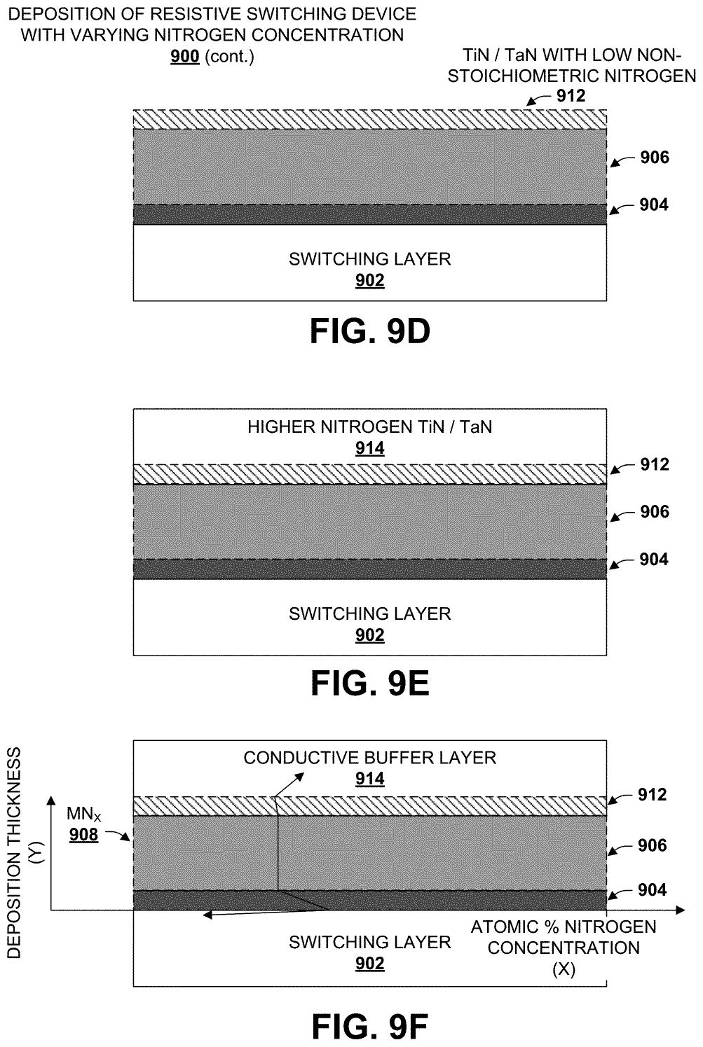

In some embodiments, first metal nitrogen region 702 can be formed with a PVD process that sputters the metal of the metal nitrogen in a nitrogen and argon gas environment. In such embodiment(s), first metal nitrogen region 702 can be formed by sputtering the metal material with about 500 W (or a range within +1-10% of 500 W) of power and about a 1 to 10 ratio of N₂ gas to Ar gas in the nitrogen and argon gas environment. As one example, the metal material can be an aluminum metal (optionally including up to about 2% of Si, W or both) as the sputtering target. Other metals for disclosed metal nitrogen materials (optionally including up to about 2% of Si, W or both) can be utilized instead. Second metal nitrogen region 704 can be formed by changing the nitrogen and argon gas environment to about a 1 to 12 ratio of N₂ gas to Ar gas with the 500 W (+/−10%) of sputtering power. In an embodiment(s), first metal nitrogen region 702 can be about 50 angstroms (Å) thick, and second metal nitrogen region 704 can be about 300 A thick. In at least one such embodiment, third metal nitrogen region 706 is not formed, and instead TiN/TaN electrode material 712 is formed initially with lower nitrogen percentage for a first region of TiN/TaN electrode material 712, and subsequently with ah higher nitrogen percentage for a second region of TiN/TaN electrode material 712 (see FIGS. 9-9F, infra; e.g., 912 and 914 of FIG. 9E).

In alternative embodiments, first metal nitrogen region 702 can be formed with a PVD process by sputtering a metal target with 500 W of power (+/−10%), and a nitrogen and argon gas environment with about a 1 to 8 ratio of N₂ gas to Ar gas. Second metal nitrogen region 704 can then be formed by changing the nitrogen and argon gas environment to about a 1 to 12 ratio of nitrogen to argon gas. In such embodiments, third metal nitrogen region 706 can then be formed by increasing sputtering power to about 750 W (+/−10%) while retaining the (about) 1 to 12 ratio of nitrogen to argon gas environment. In at least one such embodiment(s), first metal nitrogen region 702 can be about 50 A, second metal nitrogen region 704 can be about 300 A and third metal nitrogen region 706 can be about 50 A.

In still further embodiments, first metal nitrogen region 702 can be formed by PVD process including sputtering a metal target with 500 W of power (+/−10%), in a nitrogen and argon gas environment of about 1 to 10 ratio of N₂ gas to Ar gas. Second metal nitrogen region 704 can then be formed by changing the nitrogen and argon gas environment to about 1 to 12 ratio of N₂ gas to Ar gas with the sputtering power in the same range (500 W+1-10%), and third metal nitrogen region 706 can then be formed by changing the nitrogen and argon gas environment to about 1 to 15 ratio of N₂ gas to Ar gas with the sputtering power in the same range (500 W+/−10%). Similar to the above embodiments, first metal nitrogen region 702 can be about 50 A, second metal nitrogen region 704 can be about 300 A and third metal nitrogen region 706 can be about 50 A.

In various embodiments, MNₓ layer 710—including first metal nitrogen region 702, second metal nitrogen region 704 and optionally third metal nitrogen region 706—can be formed from a continuous deposition that involves process parameters changed in real time during the deposition, to form a smooth gradient of nitrogen concentration according to the concentrations listed above. In other embodiments, one or more of the respective metal nitrogen regions 702, 704, 706 of MNₓ layer 710 can be formed as a discrete sub-layer(s) in which deposition is stopped before or following the sub-layer(s), process parameters are reset to form the sub-layer(s) or subsequent region(s), and then deposition restarts according to the reset process parameters.

In alternative embodiments, suitable combinations of the following process parameters can be utilized to achieve desired nitrogen concentrations of MNₓ layer 710. Temperature in a range of 25 C to 150 C; sputtering power in a range from 200 W to 5000 W; pressure in a range of 1 milliTorr (mT) to 10 mT (e.g., about 4-6 mT, about 5 mT, etc.); N₂ gas to Ar gas flow ratio of about 1 to 8 to about 1 to 20 (e.g., about 10-15 ratio; about 11-13 ratio; about 12 ratio, and so forth). Any suitable value or range between the above ranges for one or more parameters (e.g., temperature and pressure), alone and in combination with any suitable value or range between the above ranges of one or more other of the parameters (e.g., sputtering power and gas ratio), are within the scope of the present disclosure.

In one or more embodiments, TiN/TaN electrode material 712 can be deposited via PVD process. TiN/TaN electrode material 712 can be a non-stoichiometric (e.g., non-crystalline, amorphous, etc.) material of about 40% nitrogen and remainder Ti or Ta metal by atomic concentration. In at least one embodiment, TiN/TaN electrode material 712 can initially be deposited (or deposited with an initial sub-layer) having about 15-20% nitrogen concentration, and remainder Ti or Ta metal (e.g., see FIG. 9E, infra). As one example, this initial deposition can be a thickness of 50 A to 100 A. Subsequently, a remainder of TiN/TaN electrode material 712 can have the 40% nitrogen concentration. The initial deposition of 15-20% nitrogen concentration can be utilized to mitigate or avoid increasing the nitrogen concentration of MNₓ layer 710 below TiN/TaN electrode material 712 (e.g., third metal nitrogen region 706, though potentially including second metal nitrogen region 704 and first metal nitrogen region 702) after completing the deposition of MNₓ layer 710 to its desired nitrogen concentration (e.g., as provided above).

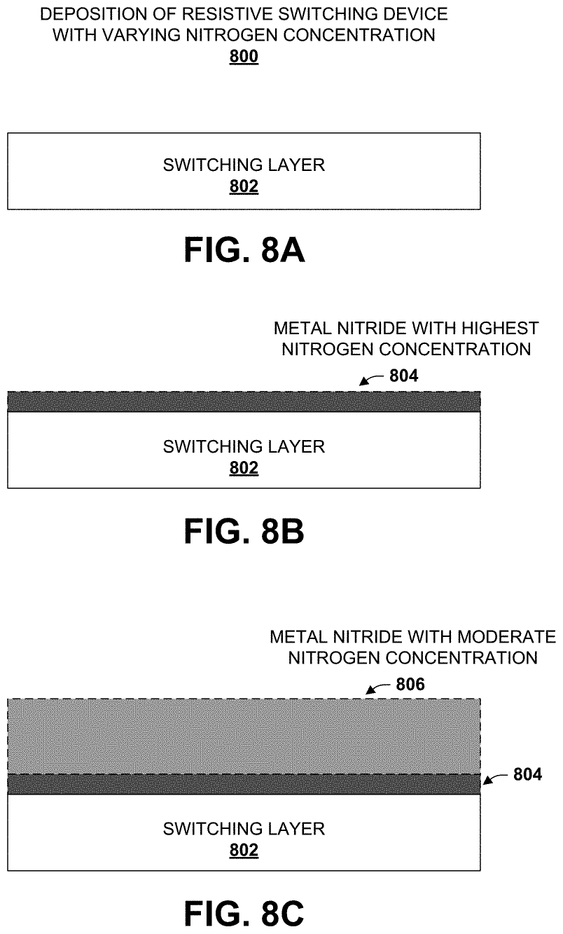

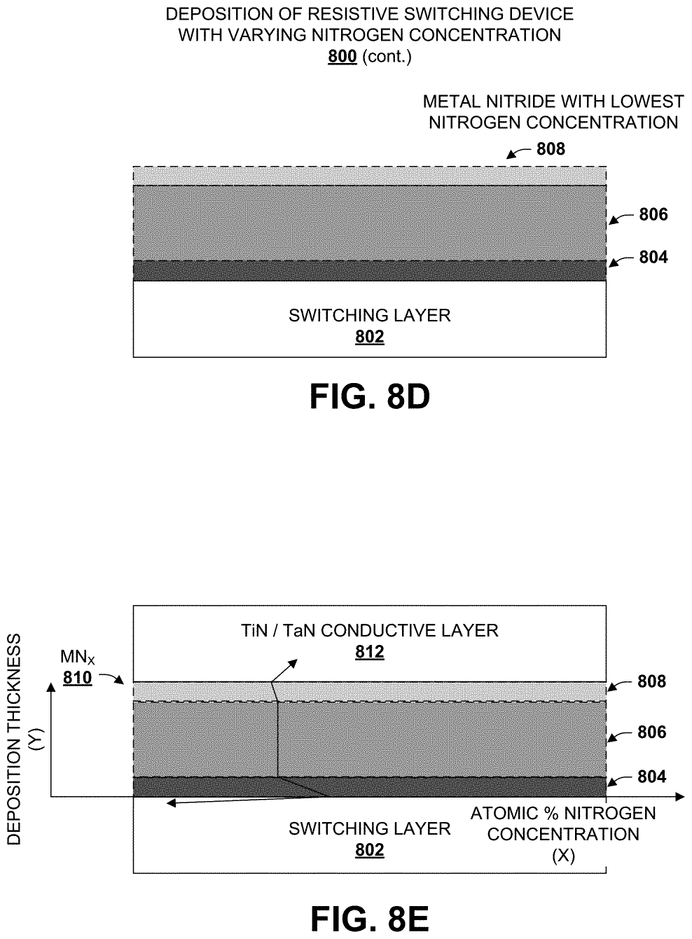

FIGS. 8A-8E illustrate an example deposition 800 for fabricating a two-terminal resistive switching device according to one or more disclosed embodiments. Although some layers are illustrated as having discrete sub-layers, it should be understood that the illustrated layers or sub-layers can be formed with discrete deposition processes, with parameters established for a given layer or sub-layer, or can be formed with continuous deposition processes that change from one layer or sub-layer to another, as suitable.

FIG. 8A depicts a diagram of a switching layer 802. Switching layer 802 can be formed overlying one or more other layers of a semiconductor device (e.g., including but not limited to a conductive layer 714). Switching layer 802 can be formed of any suitable material disclosed herein, or by any process disclosed herein. In at least one example, switching layer 802 is formed of an AlO_{y} material. FIG. 8B illustrates a deposition of a first metal nitrogen region 804 of a metal nitrogen active layer (or particle donor layer). Metal nitrogen region 804 can have a highest (relative) nitrogen concentration for the active layer. Metal nitrogen region 804 can have a substantially constant nitrogen concentration in a range of about 20 to about 30 percent, in some embodiments, or can have a decreasing nitrogen concentration starting at a higher value in the range of about 20 percent to about 30 percent (e.g., about 28 percent) to a smaller value in the range of about 20 percent to about 30 percent (e.g., about 20 to 22 percent). Metal nitrogen region 804 can be about 50 A thick in one or more embodiments.

FIG. 8C illustrates a deposition of a metal nitrogen region 806 having a moderate nitrogen concentration (e.g., about 15 to about 20% nitrogen concentration). Metal nitrogen region 806 can be about 300 A thick in at least one embodiment. FIG. 8D is illustrated as a metal nitrogen region 808 having low nitrogen concentration (e.g., about 10 to about 15% nitrogen concentration). In various embodiments, metal nitrogen region 808 can have a thickness of about 50 A in various embodiments. In combination, metal nitrogen regions 804, 806 and 808 form a MNₓ layer 810, having relative nitrogen concentration as illustrated in FIG. 8E along X axis as a function of deposition thickness along Y axis. Overlying MNₓ layer 810 is a TiN/TaN conductive layer 812.

FIGS. 9A-9F illustrate an example deposition 900 for fabricating a two-terminal resistive switching device according to one or more disclosed embodiments. Although some layers are illustrated as having discrete sub-layers, it should be understood that the illustrated layers or sub-layers can be formed with discrete deposition processes, with parameters established for a given layer or sub-layer, or can be formed with continuous deposition processes that change from one layer or sub-layer to another, as suitable.

FIG. 9A depicts a switching layer 902 that can be formed overlying one or more other layers of a semiconductor device. FIG. 9B depicts deposition of a metal nitrogen region 904 with highest nitrogen concentration (e.g., about 20 to about 30 percent nitrogen concentration). Metal nitrogen region 904 can be about 50 A thick in an embodiment. FIG. 9C depicts a metal nitrogen region 906 with moderate nitrogen concentration (e.g., about 15 to about 20 percent nitrogen concentration). FIG. 9D depicts a TiN/TaN deposition 912 concentration with low non-stoichiometric nitrogen concentration (e.g., about 15 to about 20 percent nitrogen concentration). In various embodiments, TiN/TaN deposition 912 can be about 50 A to about 100 A. FIG. 9E depicts a second TiN/TaN deposition 914 concentration with higher non-stoichiometric nitrogen concentration (e.g., about 40 percent nitrogen concentration). FIG. 9F illustrates nitrogen concentration profile (along X axis) for deposition thickness (along Y axis) for MNₓ layer 908 and TiN/TaN deposition 912.

The diagrams included herein are described with respect to interaction between several components of a memory device or an integrated circuit device, or memory architectures comprising one or more memory devices or integrated circuit devices. It should be appreciated that such diagrams can include those components, devices and architectures specified therein, some of the specified components/devices, or additional components/devices. Sub-components can also be implemented as electrically connected to other sub-components rather than included within a parent device. Additionally, it is noted that one or more disclosed processes can be combined into a single process providing aggregate functionality. For instance, a deposition process can comprise an etching process, or vice versa, to facilitate depositing and etching a component of an integrated circuit device by way of a single process. Components of the disclosed architectures can also interact with one or more other components not specifically described herein but known by those of skill in the art.

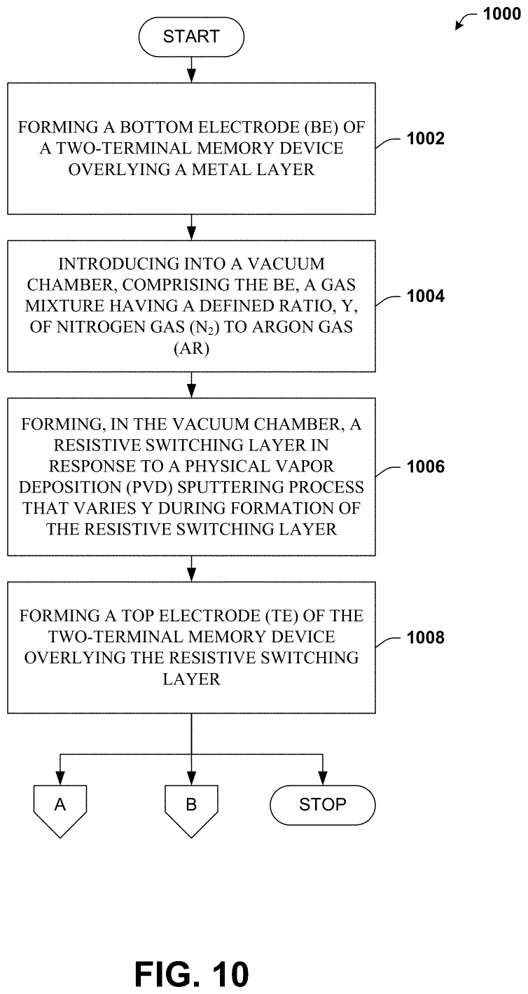

In view of the exemplary diagrams described supra, process methods that can be implemented in accordance with the disclosed subject matter will be better appreciated with reference to the flow charts of FIGS. 10-13. While for purposes of simplicity of explanation, the methods of FIGS. 10-13 are shown and described as a series of blocks, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein. Additionally, it should be further appreciated that the methods disclosed throughout this specification are capable of being stored on an article of manufacture to facilitate transporting and transferring such methodologies to an electronic device. The term article of manufacture, as used, is intended to encompass a computer program accessible from any computer-readable device, device in conjunction with a carrier, or storage medium.

Referring now to FIG. 10, exemplary method 1000 is illustrated.

Method 1000 can provide for fabrication of a two-terminal memory device that varies a gas mixture during fabrication of the switching layer in accordance with certain embodiments of this disclosure. For example, at reference numeral 1002, a two-terminal memory fabrication device can form a bottom electrode (BE) overlying a metal layer. In some embodiments, the metal layer can represent a bitline, wordline, or the like and can in some embodiments comprise copper or another suitable material. In some embodiments, the metal layer can be formed overlying a substrate. In some embodiments, the BE can be formed in a vacuum chamber or placed in the vacuum chamber during fabrication of the two-terminal memory device.

At reference numeral 1004, the fabrication device can introduce into the vacuum chamber that comprises the BE, a gas mixture having a defined ratio, Y, of nitrogen gas (N₂) to argon gas (Ar). In some embodiments, the gas mixture can be composed substantially entirely of some combination of N₂ and Ar. In other embodiments, the gas mixture can comprise other suitable gases in addition to N₂ and Ar. Regardless of whether other gases are present, the gas mixture can have a ratio referred to herein as Y, that represents a ratio of N₂:Ar

At reference numeral 1006, the fabrication device can form, in the vacuum chamber, a resistive switching layer in response to a physical vapor deposition (PVD) sputtering process. The PVD sputtering process can vary the defined ratio, Y, during formation of the resistive switching layer. The manner in which Y is varied during formation of the resistive switching layer can be according to a defined scheme that is determined to vary Y in an advantageous or desirable manner. For example, the variance of Y can be defined to be distinct from manufacturing imprecision, defects, or contaminants, or other unintentional variances.

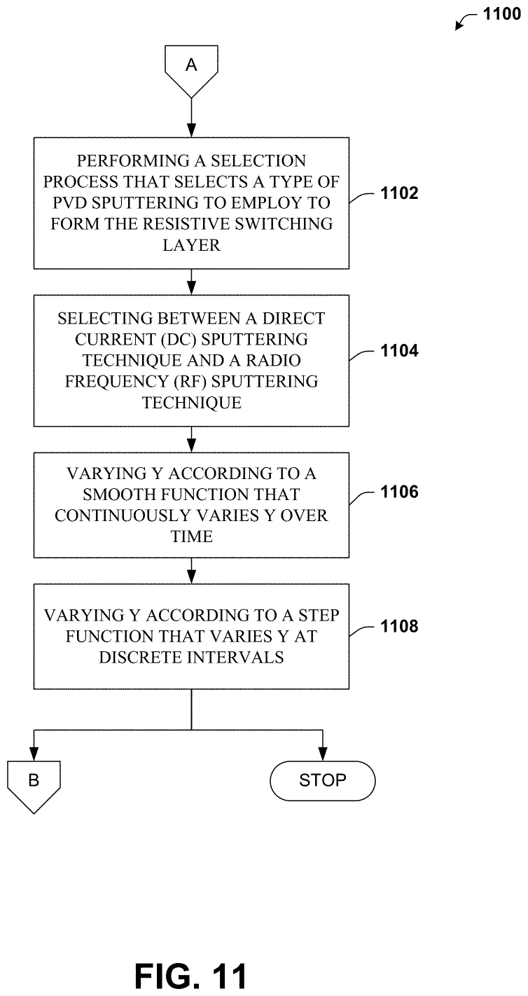

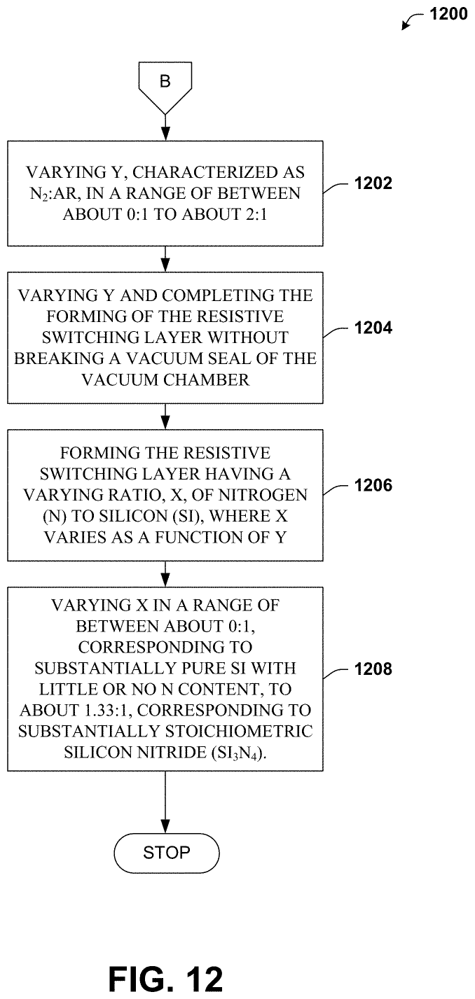

At reference numeral 1008, the fabrication device can form a top electrode (TE) of the two-terminal memory device. The TE can be formed overlying the resistive switching layer. Method 1000 can end, proceed to tab A, which is further discussed in connection with FIG. 11, or tab B, which is further discussed in connection with FIG. 12.

Turning now to FIG. 11, exemplary method 1100 is illustrated. Method 1100 can provide for selecting a type of PVD sputtering and selecting a type of variance of the defined ratio, Y, in accordance with certain embodiments of this disclosure. At reference numeral 1102, the fabrication device can perform a selection process that selects a type of PVD sputtering to employ to form the resistive switching layer.

At reference numeral 1104, the fabrication device can select between a direct current (DC) sputtering technique and a radio frequency (RF) sputtering technique. For example, fabrication of the switching layer is not limited to one or the other of DC sputtering and RF sputtering. Rather, either or both DC sputtering or RF sputtering can be employed. It is understood that DC sputtering is typically used in connection with forming films comprising metals or other conductive materials, whereas RF sputtering is typically used in connection with forming films comprising insulators. Hence, previous techniques select one or the other, but typically do not have the capacity to utilize either or both DC sputtering and RF sputtering.

At reference numeral 1106, the fabrication device that varies the defined ratio, Y, during formation of the resistive switching layer as detailed at reference numeral 1006 of FIG. 10, can vary Y according to a smooth function that continuously or substantially continuously varies Y over time. Additionally or alternatively, at reference numeral 1108, the fabrication device can vary Y according to a step function that varies Y at discrete intervals.

Turning now to FIG. 12, exemplary method 1200 is illustrated. Method 1200 can provide for additional elements or aspects in connection with fabrication of a two-terminal memory device that varies a gas mixture during fabrication of the switching layer in accordance with certain embodiments of this disclosure.

As was previously noted, the defined ratio, Y, which can be varied by the fabrication device at reference numerals 1006, 1106, and 1108, can be characterized as N₂:Ar. At reference numeral 1202, the fabrication device can vary Y in a range of between about 0:1 to about 2:1. Put differently, the ratio, Y, in the gas mixture can range from little or no N₂ (e.g., substantially entirely argon gas) to having twice the amount of N₂ as Ar.

At reference numeral 1204, the fabrication device can vary Y and complete the forming of the resistive switching layer without breaking a vacuum seal of the vacuum chamber. In some embodiments, such can avoid or mitigate contamination and composition control issues that might arise during fabrication.

At reference numeral 1206, the fabrication device can form the resistive switching layer having a varying ratio, X, of N to Si, where X can vary as a function of the defined ratio, Y. For example, the amount of nitrogen content within a given strata of the resistive switching layer (e.g., see FIGS. 5A-6D) can be a function of the amount of nitrogen gas included in the gas mixture used during formation of the resistive switching layer (e.g., see FIG. 10).

At reference numeral 1208, the fabrication device can vary X by modulating the gas flow and varying Y. Such can be accomplished such that X varies in a range of between about 0:1, corresponding to substantially pure Si with little or no N content, to about 1.33:1, corresponding to substantially stoichiometric silicon nitride (Si₃N₄).

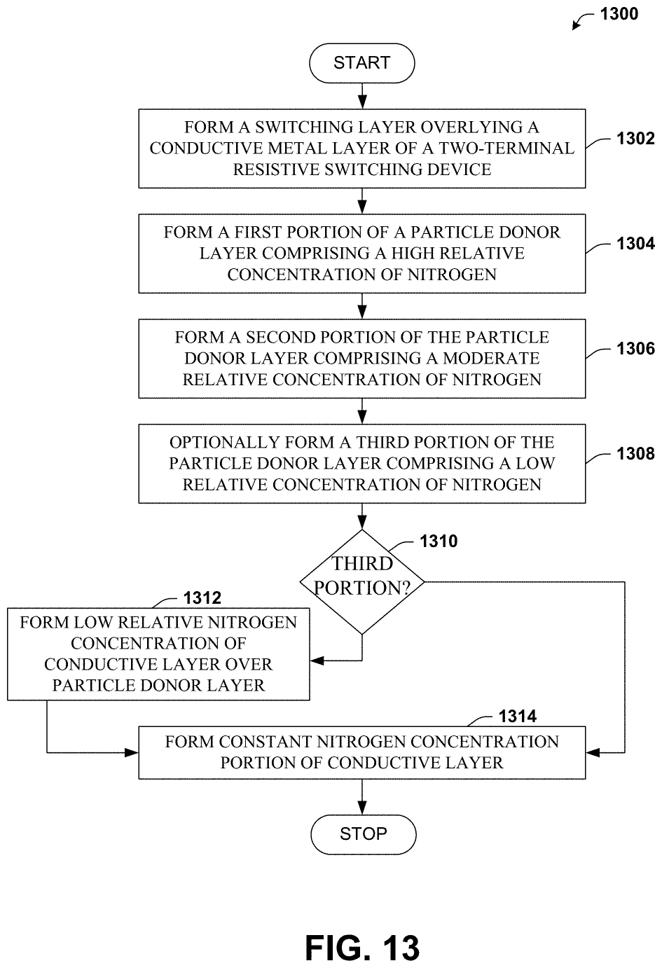

FIG. 13 illustrates a flowchart of an example method 1300 for fabricating a two-terminal resistive switching device according to alternative or additional embodiments of the present disclosure. At 1302, method 1300 can comprise forming a switching layer overlying a conductive metal layer of a two-terminal resistive switching device. At 1304, method 1300 can comprise forming a first portion of a particle donor layer overlying the switching layer of a metal and nitrogen material, and comprising a high relative concentration of nitrogen. At 1306, method 1300 can comprise forming a second portion of the particle donor layer comprising a moderate relative concentration of nitrogen for the metal and nitrogen material. At 1308, method 1300 can comprise optionally forming a third portion of the particle donor layer comprising a low relative concentration of nitrogen for the metal and nitrogen material. At 1310, a determination is made as to whether the optional third portion of the particle donor layer is deposited. If so, method 1300 can proceed to reference number 1314; otherwise method 1300 can proceed to reference number 1312 and can comprise forming a low relative nitrogen concentration of a conductive metal and nitrogen material overlying the particle donor layer. At 1314, method 1300 can comprise forming a constant nitrogen concentration portion of metal and nitrogen material for the conductive layer overlying the particle donor layer.

### Example Operating Environments

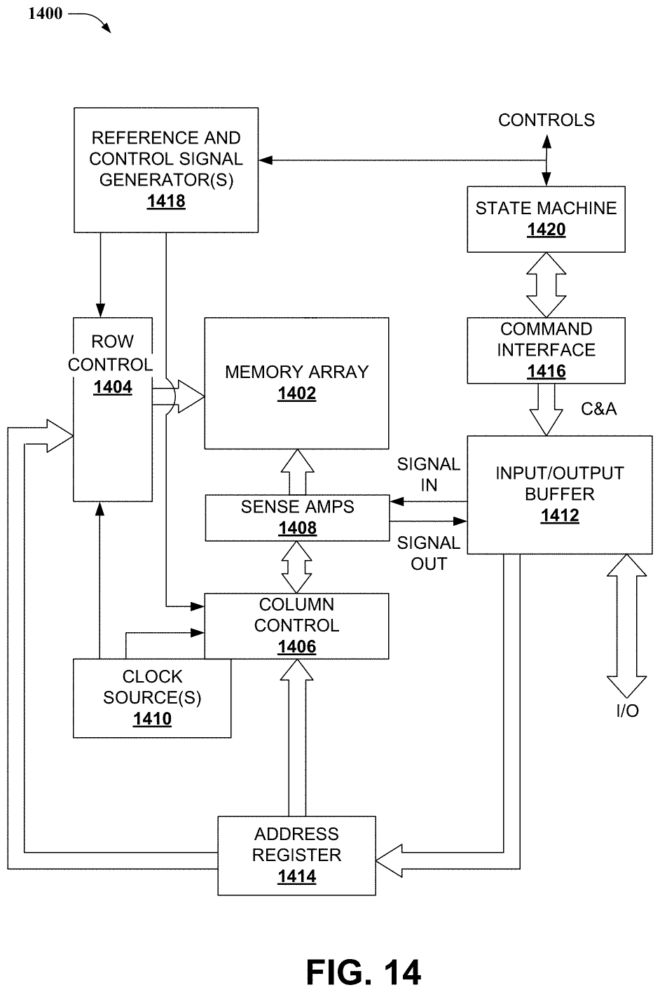

FIG. 14 illustrates a block diagram of an example operating and control environment 1400 for a memory array 1402 of a memory cell array according to aspects of the subject disclosure. In at least one aspect of the subject disclosure, memory array 1402 can comprise memory selected from a variety of memory cell technologies. In at least one embodiment, memory array 1402 can comprise a two-terminal memory technology, arranged in a compact two or three dimensional architecture. Suitable two-terminal memory technologies can include resistive-switching memory, conductive-bridging memory, phase-change memory, organic memory, magneto-resistive memory, or the like, or a suitable combination of the foregoing.

A column controller 1406 and sense amps 1408 can be formed adjacent to memory array 1402. Moreover, column controller 1406 can be configured to activate (or identify for activation) a subset of bit lines of memory array 1402. Column controller 1406 can utilize a control signal provided by a reference and control signal generator(s) 1418 to activate, as well as operate upon, respective ones of the subset of bitlines, applying suitable program, erase or read voltages to those bitlines. Non-activated bitlines can be kept at an inhibit voltage (also applied by reference and control signal generator(s) 1418), to mitigate or avoid bit-disturb effects on these non-activated bitlines.

In addition, operating and control environment 1400 can comprise a row controller 1404. Row controller 1404 can be formed adjacent to and electrically connected with word lines of memory array 1402. Also utilizing control signals of reference and control signal generator(s) 1418, row controller 1404 can select particular rows of memory cells with a suitable selection voltage. Moreover, row controller 1404 can facilitate program, erase or read operations by applying suitable voltages at selected word lines.

Sense amps 1408 can read data from, or write data to the activated memory cells of memory array 1402, which are selected by column control 1406 and row control 1404. Data read out from memory array 1402 can be provided to an input/output buffer 1412. Likewise, data to be written to memory array 1402 can be received from the input/output buffer 1412 and written to the activated memory cells of memory array 1402.

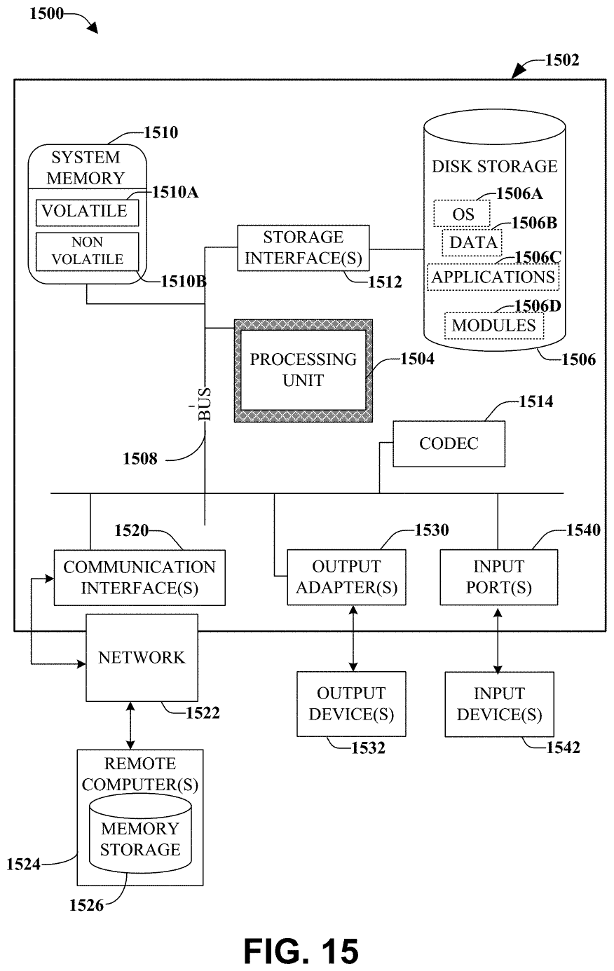

A clock source(s) 1408 can provide respective clock pulses to facilitate timing for read, write, and program operations of row controller 1404 and column controller 1406. Clock source(s) 1408 can further facilitate selection of word lines or bit lines in response to external or internal commands received by operating and control environment 1400. Input/output buffer 1412 can comprise a command and address input, as well as a bidirectional data input and output. Instructions are provided over the command and address input, and the data to be written to memory array 1402 as well as data read from memory array 1402 is conveyed on the bidirectional data input and output, facilitating connection to an external host apparatus, such as a computer or other processing device (not depicted, but see e.g., computer 1502 of FIG. 15, infra).

Input/output buffer 1412 can be configured to receive write data, receive an erase instruction, receive a status or maintenance instruction, output readout data, output status information, and receive address data and command data, as well as address data for respective instructions. Address data can be transferred to row controller 1404 and column controller 1406 by an address register 1410. In addition, input data is transmitted to memory array 1402 via signal input lines between sense amps 1408 and input/output buffer 1412, and output data is received from memory array 1402 via signal output lines from sense amps 1408 to input/output buffer 1412. Input data can be received from the host apparatus, and output data can be delivered to the host apparatus via the I/O bus.

Commands received from the host apparatus can be provided to a command interface 1416. Command interface 1416 can be configured to receive external control signals from the host apparatus, and determine whether data input to the input/output buffer 1412 is write data, a command, or an address. Input commands can be transferred to a state machine 1420.

State machine 1420 can be configured to manage programming and reprogramming of memory array 1402 (as well as other memory banks of a multi-bank memory array). Instructions provided to state machine 1420 are implemented according to control logic configurations, enabling state machine to manage read, write, erase, data input, data output, and other functionality associated with memory cell array 1402. In some aspects, state machine 1420 can send and receive acknowledgments and negative acknowledgments regarding successful receipt or execution of various commands. In further embodiments, state machine 1420 can decode and implement status-related commands, decode and implement configuration commands, and so on.

To implement read, write, erase, input, output, etc., functionality, state machine 1420 can control clock source(s) 1408 or reference and control signal generator(s) 1418. Control of clock source(s) 1408 can cause output pulses configured to facilitate row controller 1404 and column controller 1406 implementing the particular functionality. Output pulses can be transferred to selected bit lines by column controller 1406, for instance, or word lines by row controller 1404, for instance.

In connection with FIG. 15, the systems, devices, and/or processes described below can be embodied within hardware, such as a single integrated circuit (IC) chip, multiple ICs, an application specific integrated circuit (ASIC), or the like. Further, the order in which some or all of the process blocks appear in each process should not be deemed limiting. Rather, it should be understood that some of the process blocks can be executed in a variety of orders, not all of which may be explicitly illustrated herein.

With reference to FIG. 15, a suitable environment 1500 for implementing various aspects of the claimed subject matter includes a computer 1502. The computer 1502 includes a processing unit 1504, a system memory 1510, a codec 1514, and a system bus 1508. The system bus 1508 couples system components including, but not limited to, the system memory 1510 to the processing unit 1504. The processing unit 1504 can be any of various available processors. Dual microprocessors and other multiprocessor architectures also can be employed as the processing unit 1504.

The system bus 1508 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Personal Computer Memory Card International Association bus (PCMCIA), Firewire (IEEE 1394), and Small Computer Systems Interface (SCSI).

The system memory 1510 includes volatile memory 1510A and non-volatile memory 1510B. The basic input/output system (BIOS), containing the basic routines to transfer information between elements within the computer 1502, such as during start-up, is stored in non-volatile memory 1510B. In addition, according to present innovations, codec 1514 may include at least one of an encoder or decoder, wherein the at least one of an encoder or decoder may consist of hardware, software, or a combination of hardware and software. Although, codec 1514 is depicted as a separate component, codec 1514 may be contained within non-volatile memory 1510B. By way of illustration, and not limitation, non-volatile memory 1510B can include read only memory (ROM), programmable ROM (PROM), electrically programmable ROM (EPROM), electrically erasable programmable ROM (EEPROM), or flash memory, two-terminal memory, and so on. Volatile memory 1510A includes random access memory (RAM), and in some embodiments can embody a cache memory. By way of illustration and not limitation, RAM is available in many forms such as static RAM (SRAM), dynamic RAM (DRAM), synchronous DRAM (SDRAM), double data rate SDRAM (DDR SDRAM), and enhanced SDRAM (ESDRAM).

Computer 1502 may also include removable/non-removable, volatile/non-volatile computer storage medium. FIG. 15 illustrates, for example, disk storage 1506. Disk storage 1506 includes, but is not limited to, devices like a magnetic disk drive, solid state disk (SSD) floppy disk drive, tape drive, Jaz drive, Zip drive, LS-100 drive, flash memory card, or memory stick. In addition, disk storage 1506 can include storage medium separately or in combination with other storage medium including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 1506 to the system bus 1508, a removable or non-removable interface is typically used, such as storage interface 1512. It is appreciated that storage devices 1506 can store information related to a user. Such information might be stored at or provided to a server or to an application running on a user device. In one embodiment, the user can be notified (e.g., by way of output device(s) 1532) of the types of information that are stored to disk storage 1506 or transmitted to the server or application. The user can be provided the opportunity to opt-in or opt-out of having such information collected and/or shared with the server or application (e.g., by way of input from input device(s) 1542).

It is to be appreciated that FIG. 15 describes software that acts as an intermediary between users and the basic computer resources described in the suitable operating environment 1500. Such software includes an operating system 1506A. Operating system 1506A, which can be stored on disk storage 1506, acts to control and allocate resources of the computer system 1502. Applications 1506C take advantage of the management of resources by operating system 1506A through program modules 1506D, and program data 1506D, such as the boot/shutdown transaction table and the like, stored either in system memory 1510 or on disk storage 1506. It is to be appreciated that the claimed subject matter can be implemented with various operating systems or combinations of operating systems.

A user enters commands or information into the computer 1502 through input device(s) 1542. Input devices 1542 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1504 through the system bus 1508 via input port(s) 1540. Input port(s) 1540 include, for example, a serial port, a parallel port, a game port, and a universal serial bus (USB). Output device(s) 1532 use some of the same type of ports as input device(s) 1542. Thus, for example, a USB port may be used to provide input to computer 1502 and to output information from computer 1502 to an output device 1532. Output adapter 1530 is provided to illustrate that there are some output devices 1532 like monitors, speakers, and printers, among other output devices 1532, which require special adapters. The output adapters 1530 include, by way of illustration and not limitation, video and sound cards that provide a means of connection between the output device 1532 and the system bus 1508. It should be noted that other devices and/or systems of devices provide both input and output capabilities such as remote computer(s) 1538.

Computer 1502 can operate in a networked environment using logical connections to one or more remote computers, such as remote computer(s) 1524. The remote computer(s) 1524 can be a personal computer, a server, a router, a network PC, a workstation, a microprocessor based appliance, a peer device, a smart phone, a tablet, or other network node, and typically includes many of the elements described relative to computer 1502. For purposes of brevity, only a memory storage device 1526 is illustrated with remote computer(s) 1524. Remote computer(s) 1524 is logically connected to computer 1502 through a network 1522 and then connected via communication interface(s) 1520. Network 1522 encompasses wire or wireless communication networks such as local-area networks (LAN) and wide-area networks (WAN) and cellular networks. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

Communication interface(s) 1520 refers to the hardware/software employed to connect the network 1522 to the bus 1508. While communication interface(s) 1520 is shown for illustrative clarity inside computer 1502, it can also be external to computer 1502. The hardware/software necessary for connection to the network 1522 includes, for exemplary purposes only, internal and external technologies such as, modems including regular telephone grade modems, cable modems and DSL modems, ISDN adapters, and wired and wireless Ethernet cards, hubs, and routers.

As utilized herein, terms “component,” “system,” “architecture” and the like are intended to refer to a computer or electronic-related entity, either hardware, a combination of hardware and software, software (e.g., in execution), or firmware. For example, a component can be one or more transistors, a memory cell, an arrangement of transistors or memory cells, a gate array, a programmable gate array, an application specific integrated circuit, a controller, a processor, a process running on the processor, an object, executable, program or application accessing or interfacing with semiconductor memory, a computer, or the like, or a suitable combination thereof. The component can include erasable programming (e.g., process instructions at least in part stored in erasable memory) or hard programming (e.g., process instructions burned into non-erasable memory at manufacture).

By way of illustration, both a process executed from memory and the processor can be a component. As another example, an architecture can include an arrangement of electronic hardware (e.g., parallel or serial transistors), processing instructions and a processor, which implement the processing instructions in a manner suitable to the arrangement of electronic hardware. In addition, an architecture can include a single component (e.g., a transistor, a gate array, . . . ) or an arrangement of components (e.g., a series or parallel arrangement of transistors, a gate array connected with program circuitry, power leads, electrical ground, input signal lines and output signal lines, and so on). A system can include one or more components as well as one or more architectures. One example system can include a switching block architecture comprising crossed input/output lines and pass gate transistors, as well as power source(s), signal generator(s), communication bus(ses), controllers, I/O interface, address registers, and so on. It is to be appreciated that some overlap in definitions is anticipated, and an architecture or a system can be a stand-alone component, or a component of another architecture, system, etc.

In addition to the foregoing, the disclosed subject matter can be implemented as a method, apparatus, or article of manufacture using typical manufacturing, programming or engineering techniques to produce hardware, firmware, software, or any suitable combination thereof to control an electronic device to implement the disclosed subject matter. The terms “apparatus” and “article of manufacture” where used herein are intended to encompass an electronic device, a semiconductor device, a computer, or a computer program accessible from any computer-readable device, carrier, or media. Computer-readable media can include hardware media, or software media. In addition, the media can include non-transitory media, or transport media. In one example, non-transitory media can include computer readable hardware media. Specific examples of computer readable hardware media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ). Computer-readable transport media can include carrier waves, or the like. Of course, those skilled in the art will recognize many modifications can be made to this configuration without departing from the scope or spirit of the disclosed subject matter.

What has been described above includes examples of the subject innovation. It is, of course, not possible to describe every conceivable combination of components or methodologies for purposes of describing the subject innovation, but one of ordinary skill in the art can recognize that many further combinations and permutations of the subject innovation are possible. Accordingly, the disclosed subject matter is intended to embrace all such alterations, modifications and variations that fall within the spirit and scope of the disclosure. Furthermore, to the extent that a term “includes”, “including”, “has” or “having” and variants thereof is used in either the detailed description or the claims, such term is intended to be inclusive in a manner similar to the term “comprising” as “comprising” is interpreted when employed as a transitional word in a claim.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Additionally, some portions of the detailed description have been presented in terms of algorithms or process operations on data bits within electronic memory. These process descriptions or representations are mechanisms employed by those cognizant in the art to effectively convey the substance of their work to others equally skilled. A process is here, generally, conceived to be a self-consistent sequence of acts leading to a desired result. The acts are those requiring physical manipulations of physical quantities. Typically, though not necessarily, these quantities take the form of electrical or magnetic signals capable of being stored, transferred, combined, compared, and/or otherwise manipulated.

It has proven convenient, principally for reasons of common usage, to refer to these signals as bits, values, elements, symbols, characters, terms, numbers, or the like. It should be borne in mind, however, that all of these and similar terms are to be associated with the appropriate physical quantities and are merely convenient labels applied to these quantities. Unless specifically stated otherwise or apparent from the foregoing discussion, it is appreciated that throughout the disclosed subject matter, discussions utilizing terms such as processing, computing, replicating, mimicking, determining, or transmitting, and the like, refer to the action and processes of processing systems, and/or similar consumer or industrial electronic devices or machines, that manipulate or transform data or signals represented as physical (electrical or electronic) quantities within the circuits, registers or memories of the electronic device(s), into other data or signals similarly represented as physical quantities within the machine or computer system memories or registers or other such information storage, transmission and/or display devices.

In regard to the various functions performed by the above described components, architectures, circuits, processes and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the embodiments. In addition, while a particular feature may have been disclosed with respect to only one of several implementations, such feature may be combined with one or more other features of the other implementations as may be desired and advantageous for any given or particular application. It will also be recognized that the embodiments include a system as well as a computer-readable medium having computer-executable instructions for performing the acts and/or events of the various processes.

What is claimed is:

1. A two-terminal memory device, comprising:
a first electrode situated in a first region of the two-terminal memory device;
a second electrode situated in a second region of the two-terminal memory device; and
a resistive switching layer with a first portion adjacent to the first region and a second portion adjacent to the second region, wherein the resistive switching layer comprises nitrogen (N) and silicon (Si) and has a ratio, X, characterized as a first amount of N/a second amount of Si, that varies between the first portion and the second portion according to a determined variance.

2. The two-terminal memory device of claim 1, wherein X varies between the first portion and the second portion in a range of between about 0 to about 1.33.

3. The two-terminal memory device of claim 2, wherein the first portion has a first ratio, X₁ equal to about 0 and is composed substantially entirely of Si and the second portion has a second ratio, X₂ equal to about 1.33 and is composed substantially entirely of stoichiometric silicon nitride (Si₃N₄).

4. The two-terminal memory device of claim 1, wherein the determined variance is representative of a gradient function that increases or decreases the ratio, X, at a location of the resistive switching layer as a function of a height of the location.

5. The two-terminal memory device of claim 1, wherein the resistive switching layer comprises multiple sub-layers.

6. The two-terminal memory device of claim 5, wherein the determined variance is representative of a discrete sub-layer function that increases or decreases the ratio, X, by a discrete amount for respective sub-layers of the multiple sub-layers.

7. The two-terminal memory device of claim 5, wherein a thickness of a sub-layer of the multiple sub-layers is between about 1 angstrom and about 5 angstroms.

8. The two-terminal memory device of claim 1, wherein a thickness of the resistive switching layer is between about 1 angstrom and about 100 angstroms.

9. The two-terminal memory device of claim 1, wherein a thickness of the resistive switching layer is between about 10 angstrom and about 50 angstroms.

10. The two-terminal memory device of claim 1, wherein the first electrode is a bottom electrode and the second electrode is a top electrode, and wherein the two-terminal memory device is configured according to a pillar and collar configuration characterized as a first width of the bottom electrode being less than a second width of the top electrode.

11. The two-terminal memory device of claim 1, wherein the resistive switching layer is a non-volatile resistive switching layer, and wherein the two-terminal memory device is configured as a one selector, one resistor (1S1R) device characterized as having a selector device comprising a volatile resistive switching layer in series with the non-volatile resistive switching layer.

12. A method of fabricating a two-terminal memory device, comprising:
forming a bottom electrode (BE) of the two-terminal memory device overlying a metal layer;
introducing into a vacuum chamber, comprising the BE, a gas mixture having a defined ratio, Y, of nitrogen gas (N₂) to argon gas (Ar);
forming, in the vacuum chamber, a resistive switching layer in response to a physical vapor deposition (PVD) sputtering process that varies Y during formation of the resistive switching layer; and
forming a top electrode (TE) of the two-terminal memory device overlying the resistive switching layer;

13. The method of claim 12, further comprising performing a selection process that selects a type of PVD sputtering to employ to form the resistive switching layer.

14. The method of claim 13, wherein the selection process that selects the type of PVD sputtering to employ comprises selecting between a direct current (DC) sputtering technique and a radio frequency (RF) sputtering technique.

15. The method of claim 12, wherein the PVD sputtering process varies Y according to a smooth function that continuously varies Y over time.

16. The method of claim 12, wherein the PVD sputtering process varies Y according to a step function that varies Y at discrete intervals

17. The method of claim 12, wherein Y, characterized as N₂:Ar, has a range of 0:1 to about 2:1.

18. The method of claim 12, wherein the PVD sputtering process varies Y and completes the forming of the resistive switching layer without breaking a vacuum seal of the vacuum chamber.

19. The method of claim 12, wherein the forming the resistive switching layer comprises forming the resistive switching layer having a varying ratio, X, of nitrogen (N) to silicon (Si), wherein X varies as a function of Y.

20. The method of claim 19, wherein X varies in a range of between about 0:1, corresponding to substantially pure Si with little or no N content, to about 1.33:1, corresponding to substantially stoichiometric silicon nitride (Si₃N₄).
